(19) United States
(12) Patent Application Publication
(10) Pub. No.: US 2025/0185237 A1
(43) Pub. Date: Jun. 5, 2025

(54) SEMICONDUCTOR MEMORY DEVICE

(71) Applicant: Samsung Electronics Co., Ltd., Suwon-si (KR)

(72) Inventors: Changyoung Lee, Suwon-si (KR); Young Seok Park, Suwon-si (KR); ChangSik Yoo, Suwon-si (KR); Hyun-Chul Yoon, Suwon-si (KR); Jeongdon Ihm, Suwon-si (KR)

(21) Appl. No.: 18/739,668

(22) Filed: Jun. 11, 2024

(30) Foreign Application Priority Data
Nov. 30, 2023 (KR) 10-2023-0171494

(51) Int. Cl. H10B 12/00; G11C 11/408; G11C 11/4091; H01L 25/065; H10B 80/00

(52) U.S. Cl. CPC H10B 12/50; G11C 11/4085; G11C 11/4091; H01L 25/0657; H10B 12/315; H10B 80/00; H01L 2225/06524

(57) ABSTRACT

A semiconductor memory device includes a first chip including a cell region including memory cells and a dummy region that includes dummy cell transistors, and a second chip including core circuits and peripheral circuits configured to control operation of the memory cells, the first chip and the second chip overlap along a vertical direction. The dummy region of the first chip may include at least one variable resistor that includes the dummy cell transistors.

### CROSS-REFERENCE TO RELATED APPLICATION(S)

This U.S. non-provisional application claims priority under 35 USC § 119 to Korean Patent Application No. 10-2023-0171494, filed on Nov. 30, 2023, in the Korean Intellectual Property Office, the disclosure of which is herein incorporated by reference in its entirety.

### BACKGROUND

Example embodiments relate to semiconductor memory devices.

Semiconductor memory devices are used to store data and are classified into volatile memory devices and nonvolatile memory devices. Volatile memory devices lose their stored data when their power supplies are interrupted. A dynamic random access memory (DRAM), a type of volatile memory device, is used in various fields such as mobile systems, servers, or graphics devices.

Due to the increasing demand for high-density integration of semiconductor memory devices, semiconductor memory devices having a stacked structure are being developed. For example, semiconductor memory devices having a cell over peripheral (CoP) structure, in which memory cells storing data and circuits for driving the memory cells are implemented and then stacked on an additional wafer, are being developed.

### SUMMARY

Example embodiments provide a semiconductor memory device in which a chip-size gain may be secured using a CoP structure.

According to example embodiments, a semiconductor memory device includes a first chip including a cell region that includes memory cells and a dummy region that includes a set of dummy cell transistors, and a second chip including core circuits and peripheral circuits configured to control operation of the memory cells, the second chip overlapping at least a part of the first chip along a vertical direction. The dummy region of the first chip may include at least one variable resistor that includes the set of dummy cell transistors.

According to example embodiments, a semiconductor memory device includes a first chip that includes a cell region including memory cells and a dummy region that includes a set of dummy cell transistors, and a second chip including core circuits and peripheral circuits configured to control operation of the memory cells, the second chip overlapping at least a part of the first chip along a vertical direction. The dummy region of the first chip may include a first variable resistor including a first subset of dummy cell transistors, among the set of dummy cell transistors, electrically connected in series with one another and a second variable resistor including a second subset of dummy cell transistors, among the set of dummy cell transistors, electrically connected in series with one another. The second chip may include an amplifier and a pass transistor. The first and second variable resistors, the amplifier, and the pass transistor may be included in a low-dropout (LDO) regulator.

According to example embodiments, a semiconductor memory device includes a first chip that includes a cell region including memory cells and a dummy region that includes dummy cell transistors, and a second chip including core circuits and peripheral circuits configured to control operation of the memory cells, the first chip and the second chip overlap along a vertical direction. The dummy cell transistors are vertical channel transistors. The dummy region of the first chip may include a plurality of variable resistors that each include ones of the dummy cell transistors electrically connected in series to one another. A respective resistance value of each of the plurality of variable resistors may be controlled independently based on a voltage applied to a gate line of the ones of the dummy cell transistors included in a corresponding one of the plurality of variable resistors.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a conceptual diagram illustrating a configuration of a semiconductor memory device according to example embodiments.

FIG. 2A is a diagram illustrating a layout of a semiconductor memory device according to the related art.

FIG. 2B is a diagram illustrating a layout of a semiconductor memory device according to example embodiments.

FIG. 2C is a diagram illustrating a layout of a semiconductor memory device according to example embodiments.

FIG. 3A is a diagram illustrating an example of a configuration of a semiconductor memory device according to example embodiments when viewed from direction “A” of FIG. 1.

FIG. 3B is a diagram illustrating an example of a cross-section of a cell region and a core region of the semiconductor memory device of FIG. 3A.

FIG. 3C is a diagram illustrating an example of a cross-section of a cell region and a core region of the semiconductor memory device of FIG. 3A.

FIG. 4 is a diagram illustrating an example of a configuration of a semiconductor memory device according to example embodiments when viewed in the direction “A” of FIG. 1.

FIG. 5A is a diagram illustrating a dummy cell transistor according to example embodiments.

FIG. 5B is a graph illustrating a relationship between a gate voltage and drain current of the dummy cell transistor.

FIG. 5C is a diagram illustrating an example of a variable resistor implemented using the dummy cell transistor of FIG. 5A.

FIG. 5D is a diagram illustrating a structure of a variable resistor according to example embodiments.

FIG. 5E is a diagram illustrating the variable resistor of FIG. 5D using circuit symbols.

FIG. 5F is a diagram illustrating a structure of a variable resistor according to example embodiments.

FIG. 5G is a diagram illustrating the variable resistor of FIG. 5F using circuit symbols.

FIG. 6A is a diagram illustrating a configuration of an low-dropout (LDO) regulator according to example embodiments.

FIG. 6B is a diagram illustrating an example of a configuration of a semiconductor memory device according to example embodiments.

FIG. 6C is an enlarged view of the LDO regulator of FIG. 6B.

FIG. 7A is a diagram illustrating an operation of adjusting an output voltage of an LDO regulator.

FIG. 7B is a diagram illustrating an operation of adjusting an output voltage of an LDO regulator.

FIG. 7C is a diagram illustrating an operation of adjusting an output voltage of an LDO regulator.

FIG. 7D is a diagram illustrating an operation of adjusting an output voltage of an LDO regulator.

FIG. 8A is a diagram illustrating an example of a configuration of a semiconductor memory device according to example embodiments.

FIG. 8B is an enlarged view of a voltage divider of FIG. 8A.

FIG. 9 is a diagram illustrating an example of a configuration of a semiconductor memory device according to example embodiments.

FIG. 10 is a block diagram illustrating an example of a configuration of a semiconductor memory system according to example embodiments.

FIG. 11 is a block diagram illustrating an example of a semiconductor memory device according to example embodiments.

FIG. 12 is a diagram illustrating an example of a configuration of a memory cell array according to example embodiments.

FIG. 13A is a diagram illustrating a layout of a memory cell array according to example embodiments.

FIG. 13B is a perspective view illustrating the memory cell array of FIG. 13A.

FIG. 13C is a cross-sectional view taken along lines X-X1′ and Y-Y1′ of FIG. 13A.

### DETAILED DESCRIPTION

Hereinafter, example embodiments will be described with reference to the accompanying drawings.

The term such as “first,” “second,” or the like, used in various example embodiments may modify various elements regardless of an order and/or importance of the corresponding elements, and does not limit the corresponding elements.

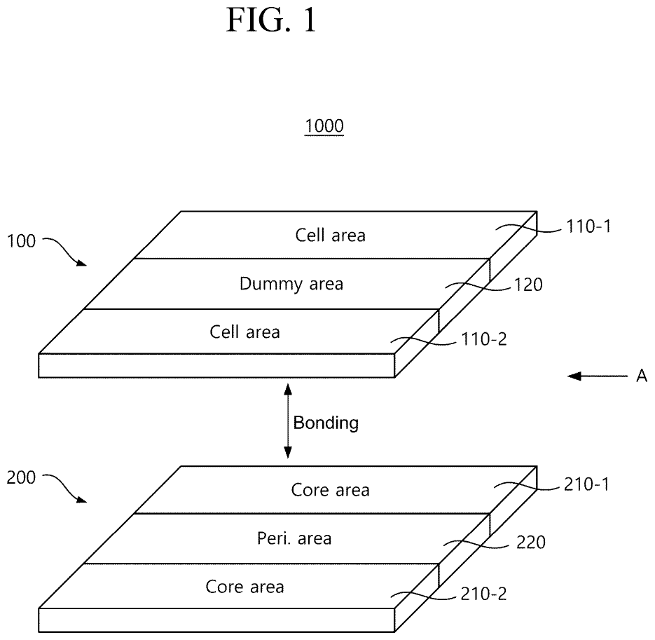

FIG. 1 is a conceptual diagram illustrating a configuration of a semiconductor memory device according to example embodiments.

Referring to FIG. 1, a semiconductor memory device 1000 may include a first chip 100 and a second chip 200. The first chip 100 and the second chip 200 may have a stacked structure. For example, the first chip 100 and the second chip 200 may have a cell over peripheral (CoP) structure.

The CoP structure may be a structure in which a first wafer including a plurality of memory cells and a second wafer including a core circuit and a peripheral circuit are each manufactured, and the first wafer is then stacked on the second wafer to electrically connect the first wafer and the second wafer. Hereinafter, the first wafer on which memory cells are disposed may be referred to as a cell wafer or a first chip. In addition, the second wafer on which core circuits and/or peripheral circuits for controlling the operation of the memory cells are disposed may be referred to as a core/peripheral wafer or a second chip.

According to example embodiments, the first chip 100 and the second chip 200 of the CoP structure may be electrically connected to each other by a bonding method. For example, the first chip 100 and the second chip 200 may be electrically connected to each other by bonding a first bonding metal formed in a lowermost portion of the first chip 100 and a second bonding metal formed in an uppermost portion of the second chip 200. According to example embodiments, the first chip 100 and the second chip 200 of the CoP structure may be electrically connected to each other by a through-silicon via (TSV) method.

The first chip 100 may include memory cells. According to example embodiments, the first chip 100 may include cell regions 110-1 and 110-2, including memory cells, and a remaining region (for example, a dummy region) 120 which does not include memory cells.

In example embodiments, the first chip 100 may include a first cell region 110-1 and a second cell region 110-2 spaced apart from each other. In addition, the first chip 100 may include a dummy region 120 disposed between the first cell region 110-1 and the second cell region 110-2. However, example embodiments are not limited thereto, and the number and locations of cell regions and dummy regions may vary according to example embodiments.

The cell regions 110-1 and 110-2 may include a memory cell array. The memory cell array may include a plurality of memory cells formed at intersections of wordlines and bitlines. According to example embodiments, the memory cell array may include a plurality of cell array mats divided for each region handled or controlled by a sub-wordline driver.

The second chip 200 may include core circuits and peripheral circuits to control the operation of the memory cells included in the first chip 100. The core circuits may include, for example, a sub-wordline driver, a bitline sense amplifier, a row decoder (or an X-decoder), and a column decoder (or a Y-decoder). The peripheral circuits may include various circuits to decode commands and control input/output of addresses and/or data. For example, the peripheral circuits may include a control logic, an address buffer, a delayed locked loop (DLL), a data input/output buffer, a power circuit, or the like. The power circuit may generate various DC voltages required for the operation of the semiconductor memory device 1000.

The second chip 200 may include core regions 210-1 and 210-2, in which core circuits are disposed, a peripheral circuit region 220 in which peripheral circuits are disposed. In this case, according to example embodiments, the core regions 210-1 and 210-2 may correspond to the cell region 110-1 and 110-2, and the peripheral circuit region 220 may correspond to the dummy region 120. For example, while the first chip 100 and the second chip 200 are bonded, the cell regions 110-1 and 110-2 may overlap the core regions 210-1 and 210-2, and the dummy region 120 may overlap the peripheral circuit region 220, but example embodiments are not limited thereto.

In example embodiments, the second chip 200 may include a first core region 210-1, including first core circuits corresponding to the memory cells included in the first cell region 110-1, and a second core region 210-2 including second core circuits corresponding to the memory cells included in the second cell region 110-2. In this case, the first core region 210-1 and the second core region 210-2 may be spaced apart from each other. In addition, the second chip 200 may include a peripheral circuit region 220 disposed between the first and second core regions 210-1 and 210-2. In this case, the peripheral circuit region 220 may include the above-described peripheral circuits.

The number and locations of the core regions and the peripheral circuit regions are not limited to the above examples, and may vary according to example embodiments. However, the number and locations of the core regions of the second chip 200 should correspond to the number and location of the cell regions of the first chip 100, and the number and location of the peripheral circuit regions of the second chip 200 should correspond to the number and location of the dummy regions of the first chip 100.

As described above, the second chip 200 may include a peripheral circuit region 220. Since the peripheral circuits are disposed in the peripheral circuit region 220, no core circuit is disposed therein. When corresponding core circuits are absent, memory cells may be incapable of operating although they are present. Therefore, memory cells may not be disposed in the dummy region 120 corresponding to the peripheral circuit region 220. For example, the first chip 100 should include a dummy region, which is the remaining region in which memory cells for data storage are not disposed.

According to example embodiments, a variable resistor may be implemented using the dummy region 120. For example, the dummy region 120 may include dummy cell transistors. Dummy cell transistors may serve as variable resistors in a linear operation area. Accordingly, in example embodiments, a variable resistor may be implemented in the dummy region 120 by serially connecting dummy cell transistors. In this case, a resistance value of the variable resistor may be controlled by adjusting a gate voltage of the serially connected dummy cell transistors in the linear operation area.

Variable resistors, implemented in the dummy region 120, may be used for the operation of peripheral circuits. For example, a voltage divider may be implemented using the variable resistors of the dummy region 120, and intermediate voltages generated by the voltage divider may be provided as reference voltages of the peripheral circuits. In addition, the variable resistors in the dummy region 120 may also be used as variable resistors for adjusting an output voltage of a low-dropout (LDO) regulator. However, example embodiments are not limited thereto, and the variable resistors in the dummy region 120 may be used for various other peripheral circuits requiring variable resistors.

According to the above-described embodiments, active resistors of a general semiconductor memory device may be replaced with the variable resistors in the dummy region 120. Thus, a chip-size gain of the semiconductor memory device 1000 may be obtained.

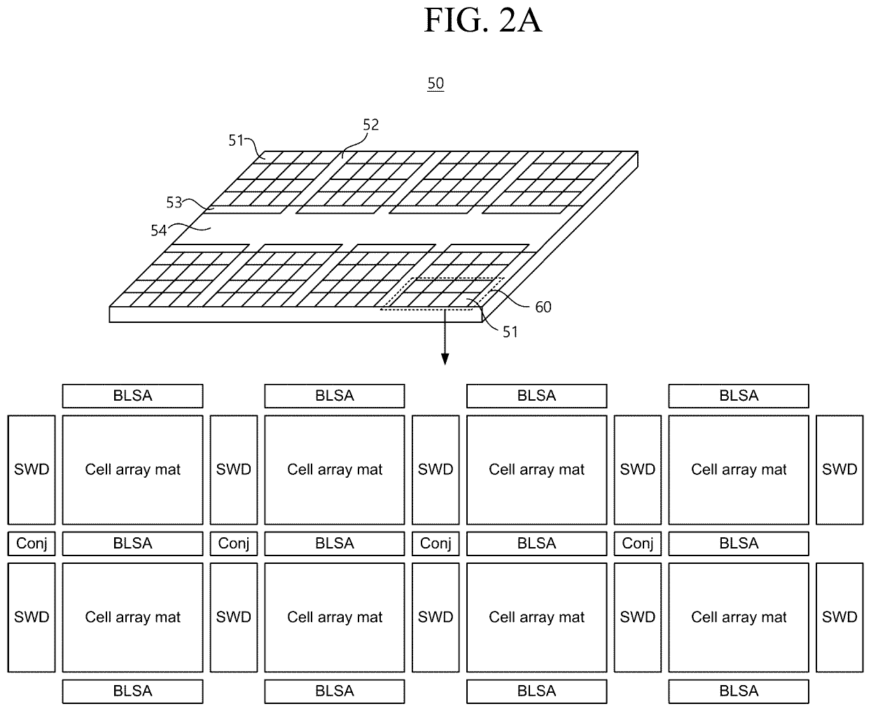

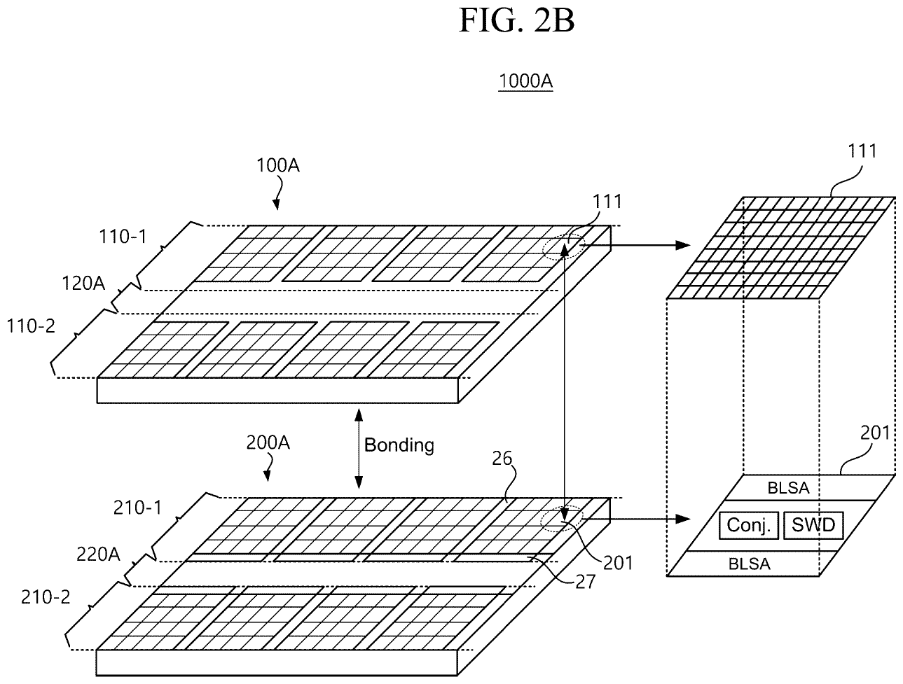

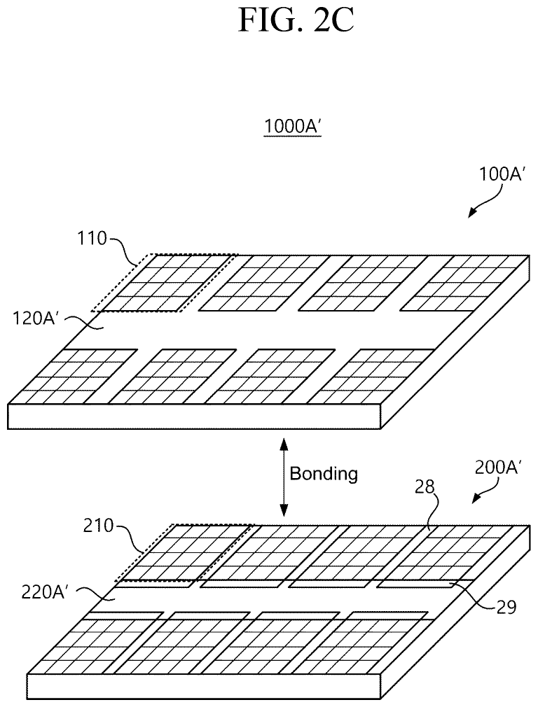

For example, in the case of a general semiconductor memory device, resistors used in DC voltage generation circuits or input/output circuits are implemented as active resistors in the peripheral circuit region (for example, a reference number 54 of FIG. 2A). Accordingly, a level of a DC voltage generated by the DC voltage generation circuit or a level of a DC voltage level used in the input/output circuits may be adjusted by changing a resistance ratio of the active resistors using, for example, a test mode register set (TMRS). However, according to example embodiments, variable resistors may be implemented using dummy cell transistors included in the dummy region 120 of the first chip 100. Accordingly, the active resistors that were implemented in the peripheral circuit region in a general semiconductor memory device may be replaced with the variable resistors in the dummy region 120. In this case, a chip-size gain may be secured by a space occupied by the active resistors.

Hereinafter, the layout of a semiconductor memory device according to example embodiments will be described with reference to FIGS. 2A and 2B.

FIG. 2A is a diagram illustrating a layout of a general semiconductor memory device. In the general semiconductor memory device, a memory cell array, core circuits, and peripheral circuits may be implemented on a single chip 50.

Referring to FIG. 2A, a unit core including a cell array mat having a predetermined size, a sub-wordline driver SWD, a bitline sense amplifier BLSA, and a conjunction region Conj may be disposed in a first region 51 of a chip 50. Unit cores may be disposed within the chip 50 in a matrix. For example, when one region 60 of the chip 50 is enlarged, the enlarged region 60 is illustrated below an arrow. For example, a plurality of sub-wordline drivers SWDs may be disposed between a plurality of cell array mats in one direction, and a plurality of bitline sense amplifiers BLSAs may be disposed between cell array mats in another direction. A plurality of conjunction regions Conj may be disposed between a plurality of sub-wordline drivers SWDs and a plurality of bitline sense amps BLSAs, respectively. According to example embodiments, a DC voltage repeater (or a DC voltage driver) may be disposed in the conjunction region Conj.

A row decoder may be arranged in a second region 52 of the chip 50, and a column decoder may be disposed in a third region 53 of the chip 50. In addition, a control logic, an address buffer, a DLL, a data input/output buffer, a power circuit, or the like, may be disposed in a fourth region 54 of the chip 50.

FIG. 2B is a diagram illustrating a layout of a semiconductor memory device according to example embodiments. Referring to FIG. 2B, a semiconductor memory device 1000A may have a CoP structure in which a first chip 100A, in which memory cells are implemented, and the second chip 200A, in which core circuits and peripheral circuits are implemented, are bonded to each other.

The first chip 100A may include a first cell region 110-1 and a second cell region 110-2. In addition, the first chip 100A may include a dummy region 120A disposed between a first cell region 110-1 and a second cell region 110-2. Each of the first cell region 110-1 and the second cell region 110-2 may include a plurality of cell array mats 111.

As compared to the first region 51 in which the unit core of FIG. 2a is arranged, a sub-wordline driver SWD, a bitline sense amplifier BLSA, or a conjunction region Conj may be absent around each cell array mat 111 of the first chip 100. In this case, a sub-wordline driver SWD, a bitline sense amplifier BLSA, and a conjunction area Conj for driving each cell array mat 111 may be disposed in the first region 201 corresponding to the cell array mat 111 in the core regions 210-1 and 210-2 of the second chip 200.

The second chip 200A may include a first core region 210-1 and a second core region 210-2. The first core region 210-1 and the second core region 210-2 may correspond to the first cell region 110-1 and the second cell region 110-2, respectively. For example, the first core region 210-1 may include first core circuits corresponding to the cell array mats 111 included in the first cell region 110-1. The second core region 210-2 may include second core circuits corresponding to the cell array mats 111 included in the second cell region 110-2.

In this case, the first and second core circuits may include a sub-wordline driver SWD, a bitline sense amplifier BLSA, and a conjunction region Conj for driving each cell array mat 111. In addition, according to example embodiments, the first and second core circuits may include a row decoder and a column decoder. The row decoder may be included in the second region 26 of the core regions 210-1 and 210-2, and the column decoder may be included in the third region 27 of the core regions 210-1 and 210-2, but example embodiments are not limited thereto.

The second chip 200A may include a peripheral circuit region 220A disposed between the first core region 210-1 and the second core region 210-2. The peripheral circuit region 220A may include peripheral circuits to control operations of the first and second core circuits. For example, the peripheral circuit region 220A may include various circuits for decoding commands and controlling the input/output of addresses and data. In example embodiments, the peripheral circuit region 220A may include a control logic, an address buffer, a DLL, a data input/output buffer, a power circuit, or the like, but example embodiments are not limited thereto.

No core circuits may be disposed in the peripheral circuit region 220A. Therefore, no memory cells may be disposed in the dummy region 120A corresponding to the peripheral circuit region 220A. According to example embodiments, the dummy region 120A may include a plurality of dummy cell transistors. When memory cells are formed in the cell regions 110-1 and 110-2, dummy cell transistors may be formed together in the dummy region 120A, but example embodiments are not limited thereto. According to example embodiments, the dummy cell transistors may be vertical channel transistors. A vertical channel transistor may include a channel layer extending in a vertical direction with respect to a substrate of the first chip 100A. The dummy region 120A may include variable resistors formed using the dummy cell transistors. For example, the dummy region 120A may include a plurality of variable resistors, each including serially connected dummy cell transistors. In this case, a resistance value of each variable resistor may vary depending on a voltage applied to gate electrodes of the dummy cell transistors included in the corresponding variable resistor.

The variable resistors implemented in the dummy region 120A may be used in various ways for the operations of the peripheral circuits included in the peripheral circuit region 220A.

In example embodiments, the dummy region 120A may include a voltage divider including a plurality of serially connected variable resistors. The voltage divider may generate at least one intermediate voltage based on a power supply voltage applied through a pad formed on an upper portion of the first chip 100A. In this case, at least one intermediate voltage may have a value obtained by dividing a power voltage by a ratio of resistance values of the variable resistors included in the voltage divider. The intermediate voltage generated by the voltage divider may be provided, as a reference voltage, to peripheral circuits among the peripheral circuits included in the peripheral circuit region 220A of the second chip 200A requiring the reference voltage.

In addition, in example embodiments, the variable resistors in the dummy region 120A may be used as one component of a low-dropout (LDO) regulator. For example, the semiconductor memory device 1000A may include an LDO regulator including a first and second variable resistor connected in series, an amplifier, and a pass transistor. In this case, the variable resistors implemented in the dummy region 120A of the first chip 100A may be used as the first and second variable resistors of the LDO regulator. The amplifier and pass transistor may be implemented in the peripheral circuit region 220A of the second chip 200A. An output voltage of the LDO regulator may vary depending on a ratio of resistance values of the first and second variable resistors, and may be used as a power supply for the peripheral circuits included in the peripheral circuit region 220A.

It should be noted that the layout illustrated in FIG. 2B is just one example, and the layout of the semiconductor memory device 1000 according to example embodiments is not limited to that illustrated in FIG. 2B.

For example, the row decoder and column decoder may be classified as peripheral circuits rather than core circuits. In this case, the cell region and the remaining region may be distinguished to be different from those of FIG. 2B, as illustrated in FIG. 2C.

FIG. 2C is a diagram illustrating a layout of a semiconductor memory device according to example embodiments. Referring to FIG. 2C, a semiconductor memory device 1000A′ may have a CoP structure in which a first chip 100A′, in which memory cells are implemented, and a second chip 200A′, in which core circuits and peripheral circuits are implemented, are bonded to each other.

The first chip 100A′ may include eight cell regions 110 and a dummy region 120A′ in which memory cells are disposed. In this case, the dummy region 120A′ may be all regions of the first chip 100A′ except for the cell regions 110. As described above, variable resistors may be implemented in the dummy region 120A′.

The second chip 200A′ may include eight core regions 210, respectively corresponding to the eight cell regions 110. Each of the core regions 210 may include a sub-wordline driver SWD and a bitline sense amplifier BLSA.

The second chip 200A′ may include a peripheral circuit region 220A′. In this case, the peripheral circuit region 220A′ may be all regions of the second chip 200A′ except for the core regions 210. For example, the peripheral circuit region 220A′ may include not only a region 220A, in which the peripheral circuits described in FIG. 2B are disposed, but also a region 28 in which the row decoder is disposed and a region 29 in which the column decoder is disposed.

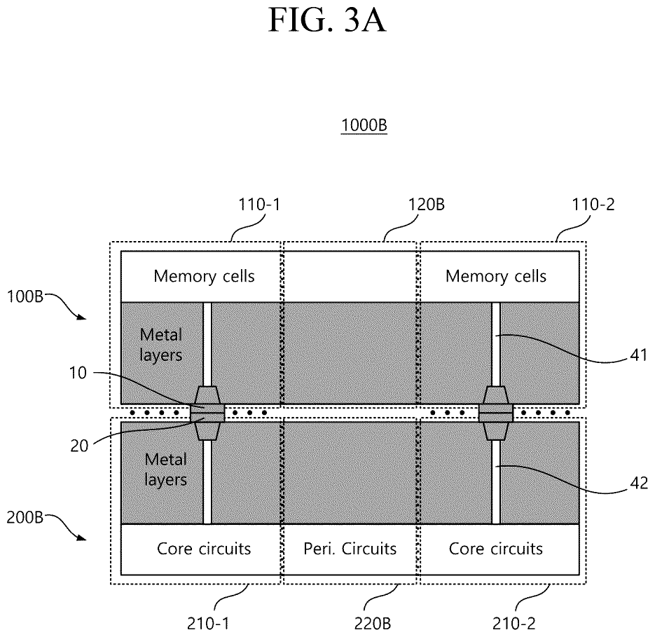

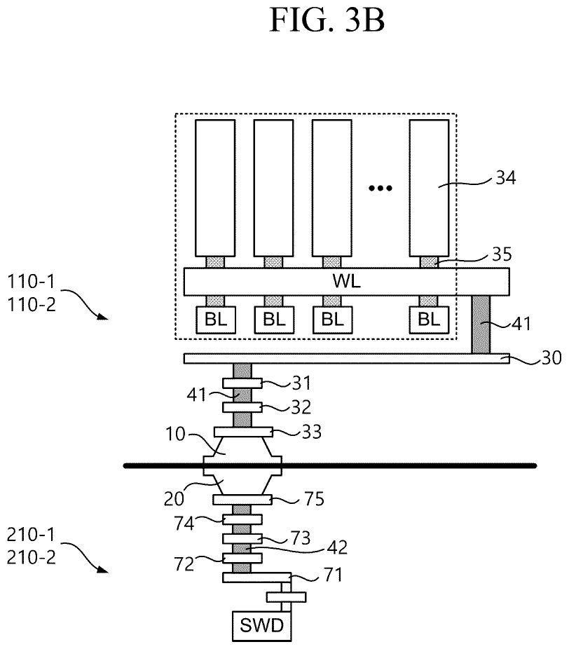

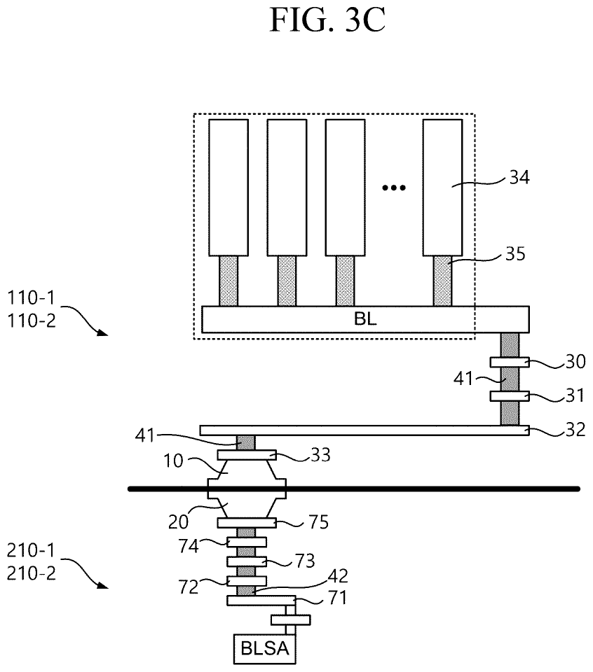

FIG. 3A is a diagram illustrating an example of a configuration of a semiconductor memory device according to example embodiments when viewed from direction “A” of FIG. 1.

The semiconductor memory device 1000B may be an example of the semiconductor memory devices 1000, 1000A, and 1000A′ of FIG. 1, FIG. 2B, and FIG. 2C, but example embodiments are not limited thereto. Referring to FIG. 3A, the semiconductor memory device 1000B may include a first chip 100B and a second chip 200B.

The first chip 100B and the second chip 200B may have a CoP structure in which the first chip 100B is stacked on the second chip 200B. According to example embodiments, the first chip 100B and the second chip 200B may be electrically connected to each other by bonding a first bonding metal 10, formed on a lowermost portion of the first chip 100B, to a second bonding metal 20 formed on an uppermost portion of the second chip 200B. In this case, a material included in the first and second bonding metals 10 and 20 may be copper (Cu). In this case, the bonding method of the first chip 100B and the second chip 200B may be referred to as a Cu—Cu bonding method. However, example embodiments are not limited thereto, the first and second bonding metals 10 and 20 may be formed of other metal materials such as aluminum (Al) or tungsten (W) according to example embodiments.

The first chip 100B may include a first cell region 110-1 and a second cell region 110-2. In addition, the first chip 100B may include a dummy region 120B disposed between the first cell region 110-1 and the second cell region 110-2. Each of the first cell region 110-1 and the second cell region 110-2 may include memory cells.

The second chip 200B may include a first core region 210-1 and a second core region 210-2. The first core region 210-1 and the second core region 210-2 may correspond to the first cell region 110-1 and the second cell region 110-2, respectively. For example, the first core region 210-1 may include first core circuits corresponding to the memory cells included in the first cell region 110-1. The second core region 210-2 may include second core circuits corresponding to the memory cells included in the second cell region 110-2.

The second chip 200B may include a peripheral circuit region 220B disposed between the first core region 210-1 and the second core region 210-2. The peripheral circuit region 220B may include peripheral circuits to control operations of the first and second core circuits.

In some embodiments, no core circuits may be disposed in the peripheral circuit region 220B. Therefore, no memory cells may be disposed in the dummy region 120B corresponding to the peripheral circuit region 220B. According to example embodiments, variable resistors connected to the peripheral circuits included in the peripheral circuit region 220B may be implemented in the dummy region 120B.

Each of the first chip 100B and the second chip 200B may include a plurality of metal layers. For example, the first chip 100B may include a plurality of metal layers below memory cells. The second chip 200B may include a plurality of metal layers above the core circuits and the peripheral circuits.

According to example embodiments, signals generated from the core circuits of the second chip 200B may be transmitted to the second bonding metal 20 through the metal layers and vias 42 of the second chip 200B. The signals transmitted to the second bonding metal 20 may be transmitted to the first chip 100B through the first bonding metal 10. The signals transmitted to the first chip 100B may be transmitted to a wordline or bitline connected to the memory cells through the metal layers and vias 41 of the first chip 100B.

FIG. 3B is an example of a cross-section of the cell region and core region of the semiconductor memory device of FIG. 3A, taken along a wordline.

Referring to FIG. 3B, the cell regions 110-1 and 110-2 may include a plurality of memory cells formed at intersections of a plurality of wordlines WL and a plurality of bitlines BL. In this case, according to example embodiments, each memory cell may be a dynamic random access memory (DRAM) cell including a vertical channel transistor 35 and a capacitor 34, but example embodiments are not limited thereto.

As described above, the first chip 100B may include a plurality of metal layers 30, 31, 32, and 33 formed below the memory cells. Each of the plurality of metal layers 30, 31, 32, and 33 may be implemented using various materials such as aluminum, copper, or tungsten, according to example embodiments. For example, in example embodiments, the first and second metal layers 30 and 31, among the plurality of metal layers 30, 31, 32, and 33, may be copper layers, and the third and fourth metal layers 32 and 33 may be tungsten layers. However, example embodiments are not limited thereto. A drive signal of the sub-wordline driver SWD, transmitted to the first chip 100B through the first and second bonding metals 10 and 20, may be applied to a wordline WL through the plurality of metal layers 30, 31, 32, and 33 and the via 41.

The core regions 210-1 and 210-2 may include core circuits corresponding to the memory cells. For example, the core regions 210-1 and 210-2 may include a sub-wordline driver SWD disposed below corresponding cell array mats. For example, the sub-wordline driver SWD may be implemented using a horizontal channel transistor, unlike the memory cells in the cell region 110-1 and 110-2. However, example embodiments are not limited thereto.

The drive signal generated by the sub-wordline driver SWD may be transmitted to the second bonding metal 20 through the plurality of metal layers 71, 72, 73, 74, and 75 and the via 42 formed on the upper portion of the sub-wordline driver SWD. In this case, each of the plurality of metal layers 71, 72, 73, 74, and 75 included in the core regions 210-1 and 210-2 may be implemented using various materials such as aluminum, copper, or tungsten, according to example embodiments.

FIG. 3C is a diagram illustrating an example of a cross-section of the cell region and core region of the semiconductor memory device of FIG. 3A, taken along a bitline. In describing FIG. 3C, duplicate descriptions with what has been described in FIGS. 3A and 3B will be omitted.

Referring to FIG. 3C, the core regions 210-1 and 210-2 may include a bitline sense amplifier BLSA disposed below corresponding cell array mats. For example, the bitline sense amplifier BLSA may be implemented using a horizontal channel transistor, unlike the memory cells in the cell regions 110-1 and 110-2. However, example embodiments are not limited thereto.

When a voltage at the bitline BL changes due to a memory cell connected to a selected wordline, a signal corresponding to the voltage change may be transmitted to the first bonding metal 10 through the plurality of metal layers 30, 31, 32, and 33 and the via 41. The signal transmitted to the second chip 200B through the first and second bonding metals 10 and 20 may be applied to the bitline sense amplifier BLSA through the plurality of metal layers 71, 72, 73, 74, and 75 and the via 42.

FIG. 3B and FIG. 3C illustrate examples of cross-sections of the cell regions 110-1 and 110-2 and the core regions 210-1 and 210-2, but each of the dummy region 120B and peripheral circuit region 220B may also include a plurality of metal layers. For example, the plurality of metal layers 30, 31, 32, and 33 included in the cell regions 110-1 and 110-2 may also be included in the dummy region 120B, and the plurality of metal layers 71, 72, 73, 74, and 75 included in the core region 210-1 and 210-2 may also be included in the peripheral circuit region 220B.

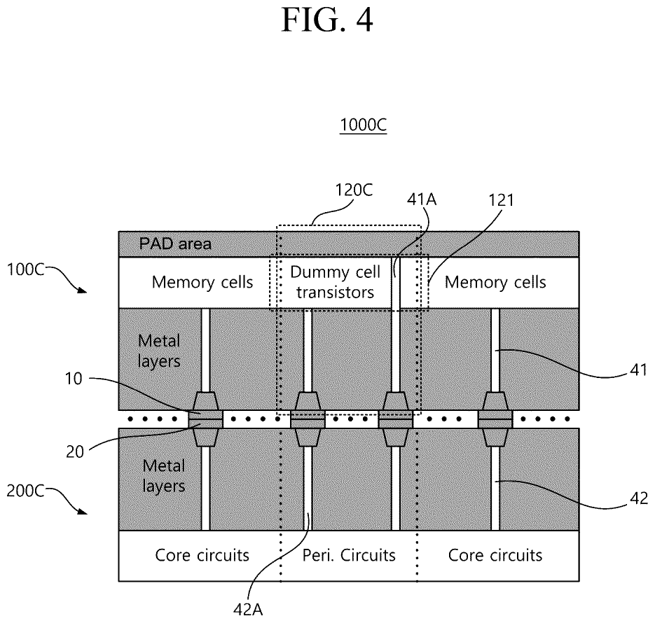

FIG. 4 is a diagram illustrating an example of a configuration of a semiconductor memory device according to example embodiments when viewed from direction “A” of FIG. 1. A semiconductor memory device 1000C may be an example of the semiconductor memory devices 1000, 1000A, 1000A′, and 1000B of FIG. 1, FIG. 2B, FIG. 2C, and FIG. 3A, but example embodiments are not limited thereto. In describing FIG. 4, duplicate descriptions with what has been described above will be omitted.

Referring to FIG. 4, the semiconductor memory device 1000C may include a first chip 100C and a second chip 200C. The first chip 100C may include a pad region. The pad region may be a region in which pads, electrically connected to an external device, are formed. As illustrated in the drawing, the pad region may be formed on an upper portion of the first chip 100C, but example embodiments are not limited thereto. Through the pads of the pad region, an address, data, a power supply voltage, or the like, may be applied to the semiconductor memory device 1000C from the outside.

The dummy region 120C of the first chip 100C may include dummy cell transistors. According to example embodiments, the dummy cell transistors may be formed together in one region 121 of the remaining region 120C when memory cells are formed in the cell region 110-1 and 110-2, but example embodiments are not limited thereto. As described above, the dummy cell transistors in the dummy region 120C may be used to implement variable resistors, and the variable resistors implemented in the dummy region 120C may be used in various ways for the operation of the peripheral circuits included in the peripheral circuit region 220B.

The first chip 100C may include vias 41A connected to the first bonding metal 10 within the dummy region 120C. The second chip 200C may include vias 42A connected to the second bonding metal 20 within the peripheral circuit region 220B. In this case, the vias 41A may connect the first bonding metal 10 to the pads of the pad region, or connect the first bonding metal 10 to the variable resistors. In addition, the vias 42A may connect the second bonding metal 20 to the peripheral circuits. Therefore, according to example embodiments, the variable resistors formed in the dummy region 120C of the first chip 100C may be connected to the peripheral circuits through the vias 41A formed in the first chip 100C, the first and second bonding metals 10 and 20, and the vias 42A formed in the second chip 200C.

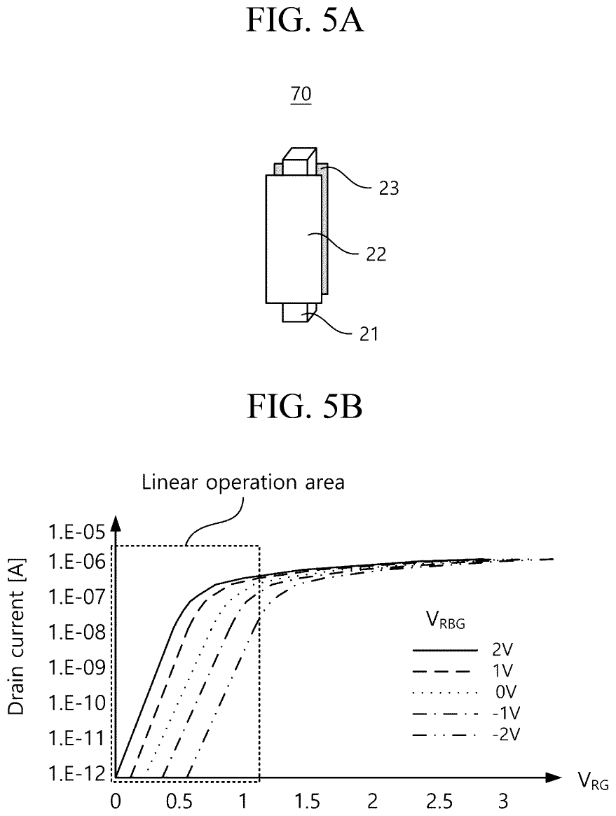

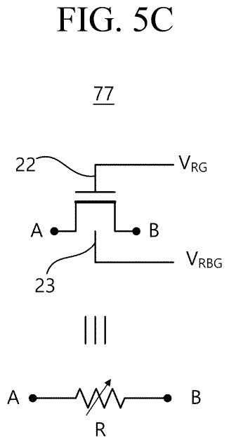

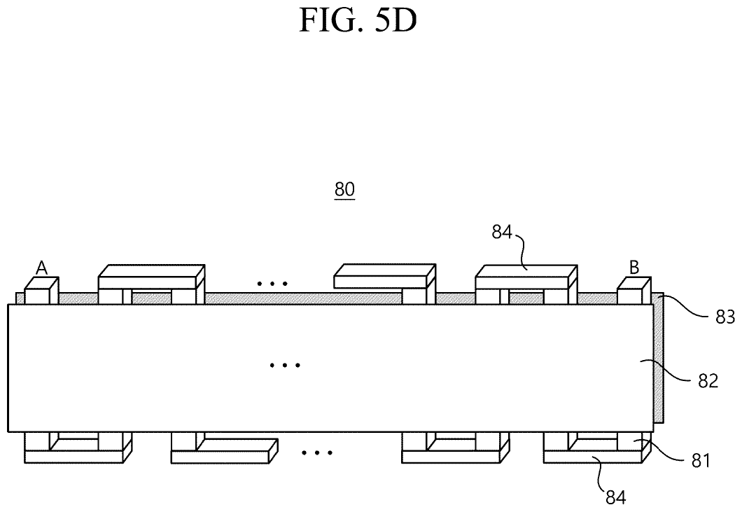

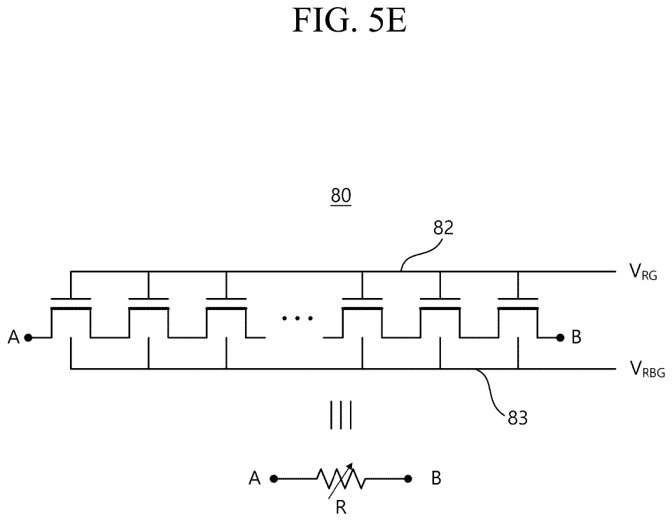

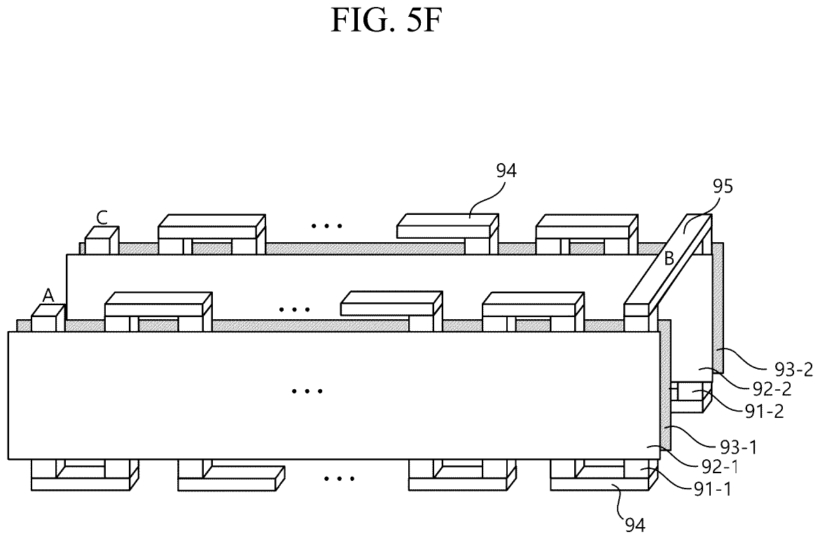

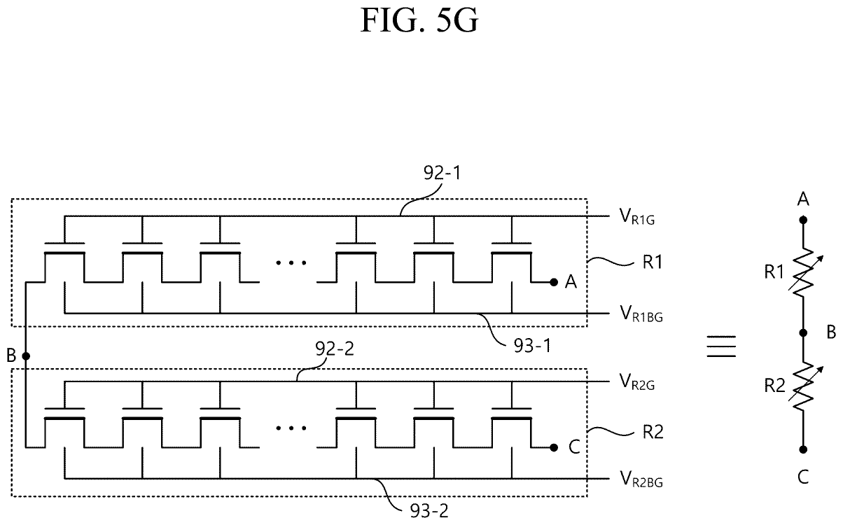

Hereinafter, the variable resistors according to various embodiments will be described with reference to FIGS. 5A, 5B, 5C, 5D, 5E, 5F, and 5G. Dummy cell transistors and variable resistors described in FIGS. 5A, 5B, 5C, 5D, 5E, 5F, and 5G may all be included in the above-described dummy region 120, 120A, 120A′, 120B, or 120C.

FIG. 5A is a diagram illustrating a dummy cell transistor according to example embodiments. Referring to FIG. 5A, a dummy cell transistor 70 may be a vertical channel transistor. In this case, the dummy cell transistor 70 may include a channel layer 21 having a length increased in a vertical direction with respect to the substrate of the first chip 100, 100A, 100A′, 100B, or 100C, a first gate electrode 22 disposed on one side of the channel layer 21, and a second gate electrode 23 disposed on the other side of the channel layer 21.

For example, a bottom portion of the channel layer 21 may serve as a first source/drain region, not illustrated, and an upper portion of the channel layer 21 may serve as a second source/drain region. A portion of the channel layer 21 between the first and second source/drain regions may serve as a channel region, not illustrated.

The dummy cell transistor 70 may be an N-type metal oxide semiconductor (NMOS) transistor. However, example embodiments are not limited thereto.

FIG. 5B is a graph illustrating a relationship between a gate voltage and drain current of the dummy cell transistor of FIG. 5A. In FIG. 5B, V_{RG} represents a first gate voltage applied to a first gate electrode 22, and V_{RBG} represents a second gate voltage applied to a second gate electrode 23.

Referring to FIG. 5B, the drain current of the dummy cell transistor 70 may increase as the gate voltage V_{RG} Or V_{RBG} increases in a linear operation area. Since a change in drain current refers to a change in resistance value, the dummy cell transistor 70 in the linear operation area may operate as a variable resistor having a resistance value adjusted based on the gate voltage V_{RG} Or V_{RBG}.

FIG. 5C is a diagram illustrating an example of a variable resistor implemented using the dummy cell transistor of FIG. 5A. Referring to FIG. 5C, a resistance value of the variable resistor 77 may vary depending on at least one of the gate voltages V_{RG} and V_{RBG}. In this case, according to example embodiments, the gate voltage V_{RG} and V_{RBG} may be controlled independently. In example embodiments, the gate voltage V_{RG} and V_{RBG} may be provided by a DC voltage supply circuit of the peripheral circuit region 220, 220A, 220A′, or 220B, but example embodiments are not limited thereto.

FIGS. 5D and 5E are diagrams illustrating a variable resistor according to example embodiments. FIG. 5D is a diagram illustrating a structure of a variable resistor according to example embodiments, and FIG. 5E is a diagram illustrating the variable resistor of FIG. 5D using circuit symbols.

Referring to FIGS. 5D and 5E together, a variable resistor 80 may include a predetermined number of serially connected dummy cell transistors. In this case, a source region of each dummy cell transistor may be connected to a drain region of an adjacent dummy cell transistor through an interconnection 84, and a drain region of each dummy cell transistor may be connected to a source region of an adjacent dummy cell transistor through an interconnection 84.

Each of the dummy cell transistors may include a channel layer 81, a first gate electrode 82 disposed on one side of the channel layer 81, and a second gate electrode 83 disposed on the other side of the channel layer 81. In this case, first gate electrodes 82 of the dummy cell transistors included in the variable resistor 80 may be connected to each other to form a first gate line, and second gate electrodes 83 of the dummy cell transistors included in the variable resistor 80 may be connected to each other to form a second gate line.

A first gate voltage V_{RG} may be applied to the first gate line, and a second gate voltage V_{RBG} may be applied to the second gate line. Therefore, a resistance value of the variable resistor 80 may vary depending on at least one of the gate voltages V_{RG} and V_{RBG}. In this case, according to example embodiments, the gate voltages V_{RG} and V_{RBG} may be controlled independently. In example embodiments, the gate voltages V_{RG} and V_{RBG} may be provided from the DC voltage supply circuit of the peripheral circuit region 220, 220A, 220A′, or 220B, but example embodiments are not limited thereto.

FIGS. 5F and 5G are diagrams illustrating a variable resistor according to example embodiments. FIG. 5F is a diagram illustrating a structure of a variable resistor according to example embodiments, and FIG. 5G is a diagram illustrating the variable resistor of FIG. 5F using circuit symbols.

Referring to FIGS. 5F and 5G together, dummy region 120, 120A, 120A′, 120B, and 120C may include a plurality of variable resistors R1, R2 each including serially connected dummy cell transistors. In this case, a source region of each dummy cell transistor included in a variable resistor R1 or R2 may be connected to a drain region of an adjacent dummy cell transistor through an interconnection 94, and a drain region of each dummy cell transistor may be connected to a source region of an adjacent dummy cell transistor through the interconnection 94. According to example embodiments, the variable resistor R1 and the variable resistor R2 may be serially connected to each other through an interconnection 95.

Each of the dummy cell transistors of the variable resistor R1 may include a channel layer 91-1, a first gate electrode 92-1 disposed on one side of the channel layer 91-1, and a second gate electrode 93-1 disposed on the other side of the channel layer 91-1. In this case, the first gate electrodes 92-1 of the dummy cell transistors included in the variable resistor R1 may be connected to each other to form a first gate line, and the second gate electrodes 93-1 of the dummy cell transistors included in the variable resistor R1 may be connected to each other to form a second gate line.

Each dummy cell transistor of the variable resistor R2 may also include a channel layer 91-2, a first gate electrode 92-2, and a second gate electrode 93-2. In this case, the first gate electrodes 92-2 of the dummy cell transistors included in the variable resistor R2 may be connected to each other to form a first gate line, and the second gate electrodes 93-2 of the dummy cell transistors included in the variable resistor R2 may be connected to each other to form a second gate line.

A first gate voltage V_{R1G} may be applied to the first gate line of the variable resistor R1, and a second gate voltage V_{R1BG} may be applied to the second gate line of the variable resistor R1. Accordingly, a resistance value of the variable resistor R1 may vary depending on at least one of the gate voltages V_{R1G} and V_{R1BG}. In this case, according to example embodiments, the gate voltages V_{R1G} and V_{R1BG} may be controlled independently.

A first gate voltage V_{R2G} may be applied to the first gate line of the variable resistor R2, and a second gate voltage V_{R2BG} may be applied to the second gate line of the variable resistor R2. Accordingly, a resistance value of the variable resistor R2 may vary depending on at least one of the gate voltages V_{R2G} and V_{R2BG}. In this case, according to example embodiments, the gate voltages V_{R2G} and V_{R2BG} may be controlled independently.

In addition, according to example embodiments, the resistance values of the serially connected variable resistors R1 and R2 may be controlled independently. For example, the gate voltages V_{R1G} and V_{R2G} may be controlled independently. The gate voltages V_{R1BG} and V_{R1BG} may be controlled independently or together, according to example embodiments.

In example embodiments, the gate voltages V_{R1G}, V_{R2G}, V_{R1BG}, and V_{R2BG} may be provided from the DC voltage supply circuit of the peripheral circuit region 220, 220A, 220A′, and 220B, but example embodiments are not limited thereto.

FIGS. 5F and 5G illustrate an example in which two variable resistors R1 and R2 are connected in series, but example embodiments are not limited thereto. In some embodiments, three or more variable resistors may be connected in series, and each of the variable resistors may have a resistance value controlled independently.

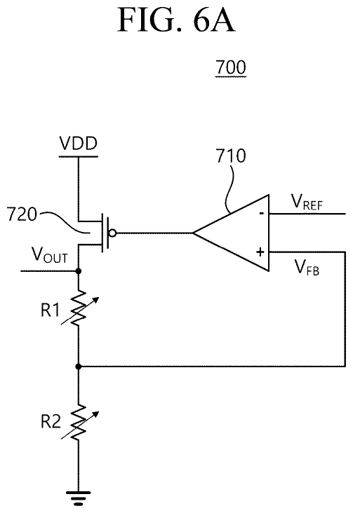

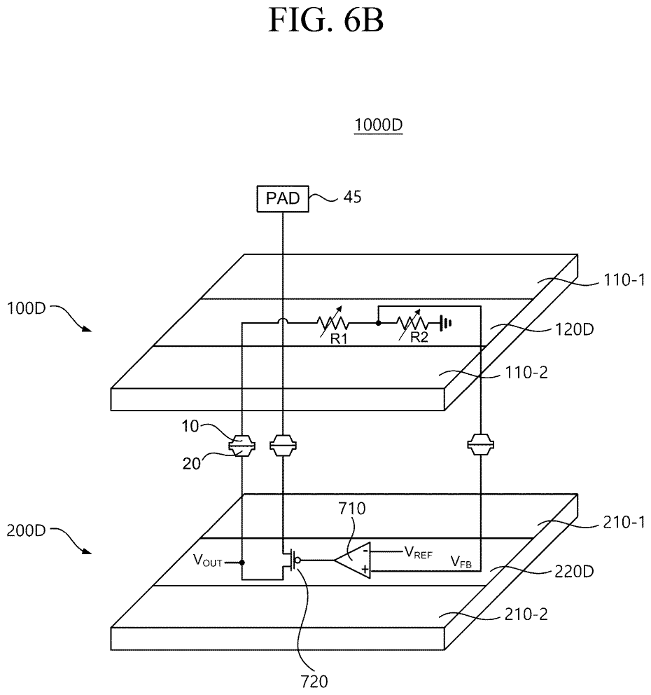

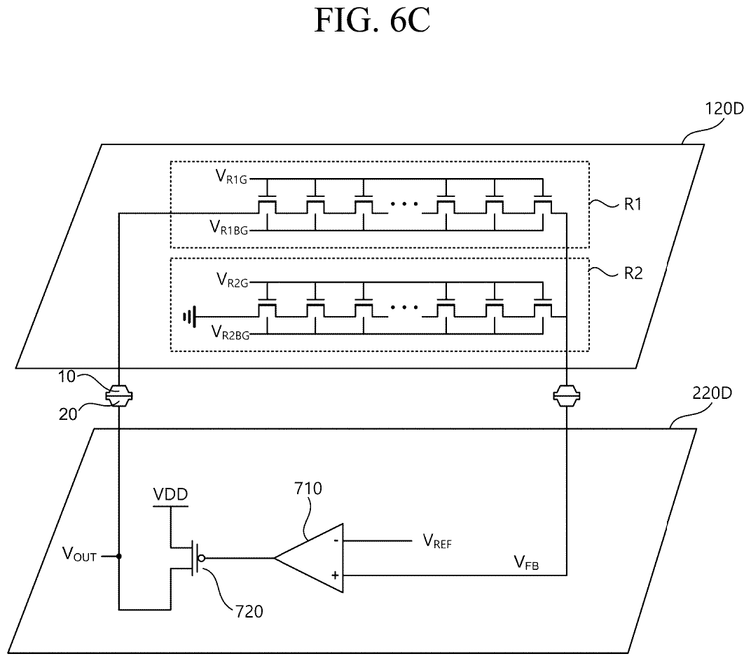

Hereinafter, an example of using a variable resistor according to example embodiments will be described with reference to FIGS. 6A, 6B, and 6C.

FIG. 6A is a diagram illustrating a configuration of an LDO regulator according to example embodiments. Referring to FIG. 6A, an LDO regulator 700 may include a first variable resistor R1 and a second variable resistor R2 connected in series, an amplifier 710, and a pass transistor 720.

The amplifier 710 may include a first input terminal (−) connected to a reference voltage VREF, a second input terminal (+) commonly connected to one end of the first variable resistor and one end of the second variable resistor, and an output terminal connected to a gate terminal of the pass transistor 720. The amplifier 710 may generate an output voltage based on a difference between a feedback voltage V_{FB} input through the second input terminal (+) and the reference voltage VREF input through the first input terminal (−), and the generated output voltage may be applied to the gate terminal of the pass transistor 720 through the output terminal.

The pass transistor 720 may include a gate terminal connected to the output terminal of the amplifier 710, a source terminal connected to the power voltage VDD, and a drain terminal connected to the other end of the first variable resistor R1. The pass transistor 720 may be a P-type metal oxide semiconductor (PMOS) transistor and may provide drain current to the other end of the first variable resistor R1 based on an output voltage of the amplifier 710.

The other end of the second variable resistor R2 may be connected to ground.

An output voltage V_{OUT} of the LDO regulator 700, output from the drain terminal of the pass transistor 720, may vary depending on a ratio of resistance values of the first and second variable resistors.

For example, when the feedback voltage V_{FB} decreases, the drain current of the pass transistor 720 may increase, so that an output voltage V_{OUT} of the LDO regulator 700 may increase. In contrast, when the feedback voltage V_{FB} increases, the drain current of the pass transistor 720 may decrease, so that an output voltage V_{OUT} of the LDO regulator 700 may decrease. Accordingly, the output voltage V_{OUT} of the LDO regulator 700 may be controlled by adjusting the feedback voltage V_{FB}.

The feedback voltage V_{FB} may be adjusted by the ratio of the resistance values of the first variable resistor R1 and the second variable resistor R2. Therefore, the output voltage V_{OUT} of the LDO regulator 700 may be adjusted by adjusting the resistance values of the first variable resistor R1 and the second variable resistor R2. For example, when the resistance value of the first variable resistor R1 increases or the resistance value of the second variable resistor R2 decreases, the feedback voltage V_{FB} may decrease. Accordingly, the output voltage V_{OUT} of the LDO regulator 700 may increase. In contrast, when the resistance value of the first variable resistor R1 decreases or the resistance value of the second variable resistor R2 increases, the feedback voltage V_{FB} may increase. Accordingly, the output voltage V_{OUT} of the LDO regulator 700 may decrease.

FIG. 6B is a diagram illustrating one configuration of a semiconductor memory device according to example embodiments. A semiconductor memory device 1000D may be an example of the above-described semiconductor memory device 1000, 1000A, 1000A′, 1000B, and 1000C, but example embodiments are not limited thereto. In describing FIG. 6D, duplicate descriptions with what has been described above will be omitted. According to example embodiments, the semiconductor memory device 1000D may include the LDO regulator 700 described in FIG. 6A.

Referring to FIG. 6B, the semiconductor memory device 1000D may include a first chip 100D and a second chip 200D having a CoP structure. In this case, a dummy region 120D of the first chip 100D may include first and second variable resistors R1 and R2 connected in series, among components of the LDO regulator 700 of FIG. 6A. A peripheral circuit region 220D of the second chip 200D may include an amplifier 710 and a pass transistor 720 of the LDO regulator 700 of FIG. 6A. The first and second variable resistors R1 and R2 of the first chip 100D and the amplifier 710 and the pass transistor 720 of the second chip 200D may be connected to each other through first and second bonding metals 10 and 20.

A pad region of the first chip 100D may include a power pad 45. A power supply voltage VDD, applied to the first chip 100D through the power pad 45, may be applied to a source terminal of the pass transistor 720 through the first and second bonding metals 10 and 20.

Although not illustrated in the drawing, the second chip 200D may include a DC voltage generation circuit to generate a reference voltage VREF. The reference voltage VREF generated by the DC voltage generation circuit may be applied to a first input terminal (−) of the amplifier 710.

The output voltage V_{OUT} of the LDO regulator may vary depending on a ratio of resistance values of the first and second variable resistors R1 and R2 and may be used as a power supply for peripheral circuits included in the peripheral circuit region 220D. Accordingly, at least a portion of the peripheral circuits of the second chip 200D may operate using the output voltage V_{OUT} of the LDO regulator 700.

In example embodiments, the first chip 100D may include vertical channel transistors, and the second chip 200D may include horizontal channel transistors. Therefore, the memory cells included in the cell regions 110-1 and 110-2 and the dummy cell transistors included in the dummy region 120D may be implemented using the vertical channel transistors, and the circuits included in the core regions 210-1 and 210-2 and the peripheral circuit region 220D may be implemented using the horizontal channel transistors.

FIG. 6C is a diagram illustrating an enlarged view of the LDO regulator of FIG. 6B. Referring to FIG. 6C, the first and second variable resistors R1 and R2 may be implemented using dummy cell transistors included in the dummy region 120D. Each of the first and second variable resistors R1 and R2 may include a predetermined number of dummy cell transistors connected in series. In addition, the first variable resistor R1 and the second variable resistor R2 may be connected in series.

First and second gate electrodes of the dummy cell transistors included in the first variable resistor R1 may form the first and second gate lines, respectively. A first gate voltage V_{R1G} may be applied to the first gate line of the first variable resistor R1, and a second gate voltage V_{R1BG} may be applied to the second gate line of the first variable resistor R1. Therefore, a resistance value of the first variable resistor R1 may vary depending on at least one of V_{R1G} and V_{R1BG}. In this case, according to example embodiments, the gate voltages V_{R1G} and V_{R1BG} may be controlled independently.

Gate electrodes of the dummy cell transistors included in the second variable resistor R2 may also form the first and second gate lines, respectively. A first gate voltage V_{R2G} may be applied to the first gate line of the second variable resistor R2, and the second gate voltage V_{R2BG} may be applied to the second gate line of the second variable resistor R2. Therefore, a resistance value of the second variable resistor R2 may vary depending on at least one of the gate voltages V_{R2G} and V_{R2BG}. In this case, according to example embodiments, the gate voltages V_{R2G} and V_{R2BG} may be controlled independently.

The resistance values of the serially connected variable resistors R1 and R2 may be controlled independently. For example, the gate voltages V_{R1G} and V_{R2G} may be controlled independently. The gate voltages V_{R1BG} and V_{R1BG} may be controlled independently or together, according to example embodiments.

Although not illustrated in the drawing, the peripheral circuit region 220D may include at least one DC voltage generation circuit generating gate voltages V_{R1G}, V_{R2G}, V_{R1BG}, and V_{R2BG}. The gate voltages V_{R1G}, V_{R2G}, V_{R1BG}, and V_{R2BG} generated by the DC voltage generation circuit may be applied to the first and second gate lines of the variable resistors R1 and R2 through first and second bonding metals 10 and 20.

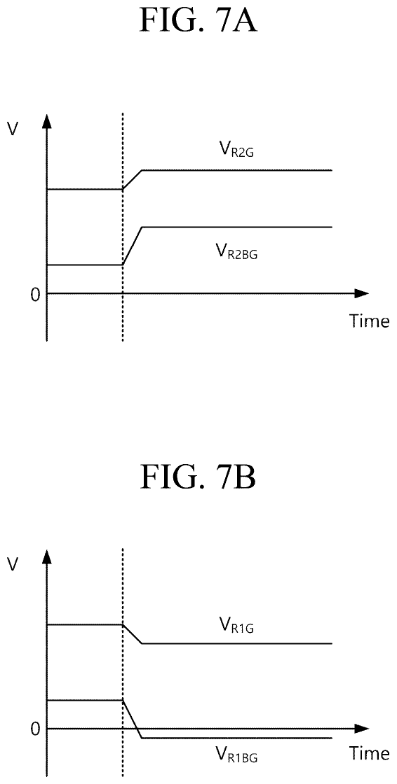

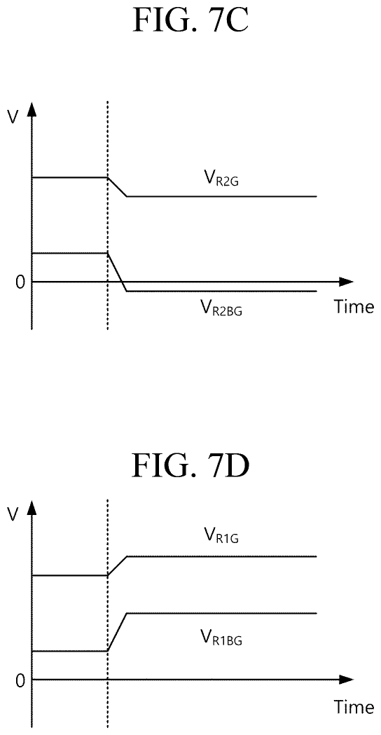

FIGS. 7A, 7B, 7C, and 7D are drawings illustrating an operation of adjusting the output voltage of the LDO regulator of FIGS. 6A, 6B, and 6C. FIGS. 7A and 7B illustrate a case in which the output voltage of the LDO regulator increases, and FIGS. 7C and 7D illustrate a case in which the output voltage of the LDO regulator decreases.

As described above, an output voltage V_{OUT} of the LDO regulator 700 may be adjusted by adjusting a feedback voltage V_{FB}. The feedback voltage V_{FB} may be adjusted based on the ratio of the resistance values of the first variable resistor R1 and the second variable resistor R2, so that the output voltage V_{OUT} of the LDO regulator 700 may be adjusted by adjusting the resistance values of the first variable resistor R1 and the second variable resistor R2.

For example, when the resistance value of the first variable resistor R1 increases or the resistance value of the second variable resistor R2 decreases, the feedback voltage V_{FB} may decrease. Accordingly, the output voltage V_{OUT} of the LDO regulator 700 may increase.

Referring to FIGS. 5B and 7A together, when the gate voltage V_{R2G} and/or V_{R2BG} increases, the drain current of the dummy cell transistors included in the second variable resistor R2 may increase, so that the resistance value of the second variable resistor R2 may decrease. Referring to FIGS. 5B and 7B together, when the gate voltage V_{R1G} and/or V_{R1BG} decreases, the drain current of the dummy cell transistors included in the first variable resistor R1 may decrease, so that the resistance value of the first variable resistor R1 may increase. Therefore, when the gate voltages V_{R1G}, V_{R2G}, V_{R1BG}, and V_{R2BG} are adjusted as illustrated FIGS. 7A and 7B, the feedback voltage V_{FB} of the LDO regulator 700 may decrease. Accordingly, the output voltage V_{OUT} of the LDO regulator 700 may increase.

When the resistance value of the first variable resistor R1 decreases or the resistance value of the second variable resistor R2 increases, the feedback voltage V_{FB} may increase. Accordingly, the output voltage V_{OUT} of the LDO regulator 700 may decrease.

Referring to FIGS. 5B and 7C together, when the gate voltage V_{R2G} and/or V_{R2BG} decreases, the drain current of the dummy cell transistors included in the second variable resistor R2 may decrease, so that the resistance value of the second variable resistor R2 may increase. Referring to FIGS. 5B and 7D together, when the gate voltage V_{R1G} and/or V_{R1BG} increases, the drain current of the dummy cell transistors included in the first variable resistor R1 may increase, so that the resistance value of the first variable resistor R1 may decrease. Therefore, when the gate voltages V_{R1G}, V_{R2G}, V_{R1BG}, and V_{R2BG} are adjusted as illustrated in FIGS. 7C and 7D, the feedback voltage V_{FB} of the LDO regulator 700 may increases. Accordingly, the output voltage V_{OUT} of the LDO regulator 700 may decrease.

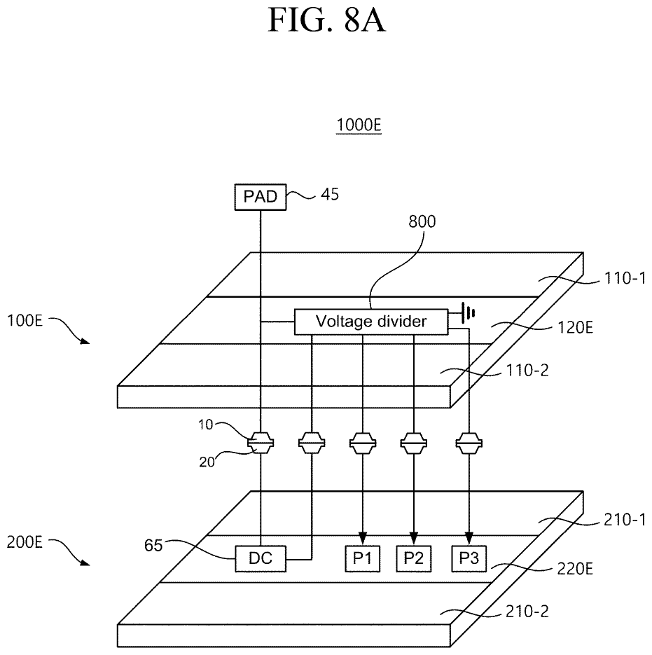

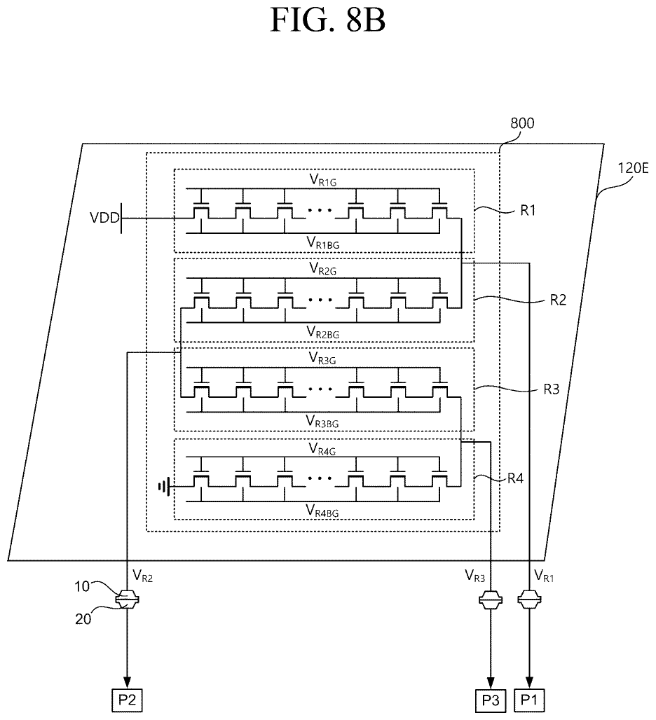

Hereinafter, an example of using a variable resistor according to example embodiments will be described with reference to FIGS. 8A and 8C.

FIG. 8A is a diagram illustrating a portion of a configuration of a semiconductor memory device according to example embodiments. A semiconductor memory device 1000E may be an example of the above-described semiconductor memory devices 1000, 1000A, 1000A′, 1000B, 1000C, and 1000D, but example embodiments are not limited thereto. In describing FIG. 8A, duplicate descriptions with what has been described above will be omitted. According to example embodiments, the semiconductor memory device 1000E may include a voltage divider.

Referring to FIG. 8A, a semiconductor memory device 1000E may include a first chip 100E and a second chip 200E having a CoP structure. In this case, a dummy region 120E of the first chip 100E may include a voltage divider 800. The voltage divider 800 may include at least two variable resistors connected in series. The variable resistors included in the voltage divider 800 may be implemented by connecting dummy cell transistors of the dummy region 120E in series, as described above.

The voltage divider 800 may generate at least one intermediate voltage based on a power supply voltage applied through a power pad 45. In this case, the at least one intermediate voltage may have a value obtained by dividing the power supply voltage by a ratio of resistance values of variable resistors included in the voltage divider 800.

A resistance value of each variable resistor included in the voltage divider 800 may be adjusted based on a gate voltage applied to a gate line of a corresponding variable resistor. Therefore, an intermediate voltage generated by the voltage divider 800 may be adjusted by the gate voltage applied to the variable resistors of the voltage divider 800. In this case, the gate voltage may be provided from a DC voltage generation circuit 65 included in a periphery region 220E. The gate voltage generated from the DC voltage generation circuit 65 may be applied to a gate line of each variable resistor of the voltage divider 800 through first and second bonding metals 10 and 20.

The intermediate voltages generated by the voltage divider 800 may be applied to peripheral circuits P1, P2, and P3 through the first and second bonding metals 10 and 20. In this case, the peripheral circuits P1, P2, and P3 may be circuits requiring a reference voltage during operation, among the peripheral circuits included in the peripheral circuit region 220E of the second chip 200E. Therefore, according to example embodiments, the peripheral circuits P1, P2, and P3 may operate using the intermediate voltages generated by the voltage divider 800 as a reference voltage.

In example embodiments, the first chip 100E may include vertical channel transistors, and the second chip 200E may include horizontal channel transistors. Therefore, the memory cells included in the cell regions 110-1 and 110-2 and the dummy cell transistors included in the dummy region 120E may be implemented using the vertical channel transistors, and the circuits included in the core regions 210-1 and 210-2 and the peripheral circuit region 220E may be implemented using the horizontal channel transistors.

FIG. 8B is an enlarged view of the voltage divider of FIG. 8A. Referring to FIG. 8B, first to fourth variable resistors R1, R2, R3, and R4 included in the voltage divider 800 may be implemented using the dummy cell transistors included in the dummy region 120E. Each of the first to fourth variable resistors R1, R2, R3, and R4 may include a predetermined number of dummy cell transistors connected in series. The first to fourth variable resistors R1, R2, R3, and R4 may be connected in series. In this case, one end of the first variable resistor R1 may be connected to a power supply voltage VDD, and one end of the fourth variable resistor R4 may be connected to ground.

A first gate electrode and a second gate electrode of the dummy cell transistors included in the first variable resistor R1 may form a first gate line and a second gate line, respectively. A first gate voltage V_{R1G} may be applied to the first gate line of the first variable resistor R1, and a second gate voltage V_{R1BG} may be applied to the second gate line. Therefore, the resistance value of the first variable resistor R1 may vary depending on at least one of the gate voltages V_{R1G} and V_{R1BG}. In this case, according to example embodiments, the gate voltages V_{R1G} and V_{R1BG} may be controlled independently.

Gate electrodes of the dummy cell transistors included in the second variable resistor R2 may also form a first gate line and a second gate line, respectively. A first gate voltage V_{R2G} may be applied to the first gate line of the second variable resistor R2, and the second gate voltage V_{R2BG} may be applied to the second gate line of the second variable resistor R2. Therefore, a resistance value of the second variable resistor R2 may vary depending on at least one of the gate voltages V_{R2G} and V_{R2BG}. In this case, according to example embodiments, the gate voltages V_{R2G} and V_{R2BG} may be controlled independently.

This concept may be applied to the third variable resistor R3 and the fourth variable resistor R4. For example, a first gate voltage V_{R3G} and a second gate voltage V_{R2BG} may be applied to a first gate line and a second gate line of the third variable resistor R3, respectively. In addition, a resistance value of the third variable resistor R3 may vary depending on at least one of the gate voltages V_{R3G} and V_{R3BG}. According to example embodiments, the gate voltages V_{R3G} and V_{R3BG} may be controlled independently. The first and second gate voltages V_{R4G} and V_{R4BG} may be applied to a first gate line and a second gate line of the fourth variable resistor R4, respectively. In addition, a resistance value of the fourth variable resistor R4 may vary depending on at least one of the gate voltages V_{R4G} and V_{R4BG}. According to example embodiments, the gate voltages V_{R4G} and V_{R4BG} may be controlled independently.

According to example embodiments, the resistance values of the first to fourth variable resistors R1, R2, R3, and R4 may be controlled independently. For example, the first gate voltages V_{R1G}, V_{R2G}, V_{R3G}, and V_{R4G} may be controlled independently. The second gate voltages V_{R1BG}, V_{R2BG}, V_{R3BG}, and V_{R4BG} may be controlled independently or together, according to example embodiments.

The voltage divider 800 may generate first to third intermediate voltages V_{R1}, V_{R2}, and V_{R3} based on the power supply voltage VDD. In this case, the first intermediate voltage V_{R1} may be generated at a node at which the first variable resistor R1 and the second variable resistor R2 are connected, the second intermediate voltage V_{R2} may be generated at a node at which the second variable resistor R2 and the third variable resistor R3 are connected, and the third intermediate voltage V_{R3} may be generated at a node at which the third variable resistor R3 and the fourth variable resistor R4 are connected.

A magnitude of each of the intermediate voltages V_{R1}, V_{R2}, and V_{R3} may vary depending on the ratio of the resistance values of the first to fourth variable resistors R1, R2, R3, and R4. As described above, the resistance value of a variable resistor may vary depending on a gate voltage applied to a gate line of a corresponding variable resistor. Therefore, the intermediate voltages V_{R1}, V_{R2}, and V_{R3} generated by the voltage divider 800 may be controlled by adjusting the gate voltages V_{R1G}, V_{R2G}, V_{R3G}, V_{R4G}, V_{R1BG}, V_{R2BG}, V_{R3BG}, and V_{R4BG}.

For example, when the first gate voltages V_{R1G}, V_{R2G}, V_{R3G}, and V_{R4G} may be the same voltage and the second gate voltages V_{R1BG}, V_{R2BG}, V_{R3BG}, and V_{R4BG} may be the same voltage, the resistance values of the first to fourth variable resistors R1, R2, R3, and R4 may have the same value. In this case, the first to third intermediate voltages V_{R1}, V_{R2}, and V_{R3} may have values of (3/4)*VDD, (2/4)*VDD, and (1/4)*VDD, respectively. However, example embodiments are not limited thereto. The gate voltages V_{R1G}, V_{R2G}, V_{R3G}, V_{R4G}, V_{R1BG}, V_{R2BG}, V_{R3BG}, and V_{R4BG} may be applied to be different from the above example, so that the first to third intermediate voltages V_{R1}, V_{R2}, and V_{R3} may be adjusted to have different values.

FIG. 8B illustrates an example in which the voltage divider 800 includes four variable resistors R1, R2, R3, and R4 and generates three intermediate voltages V_{R1}, V_{R2}, and V_{R3}, but example embodiments are not limited thereto. The number of variable resistors included in the voltage divider 800 or the number of intermediate voltages generated by the voltage divider 800 may vary according to example embodiments.

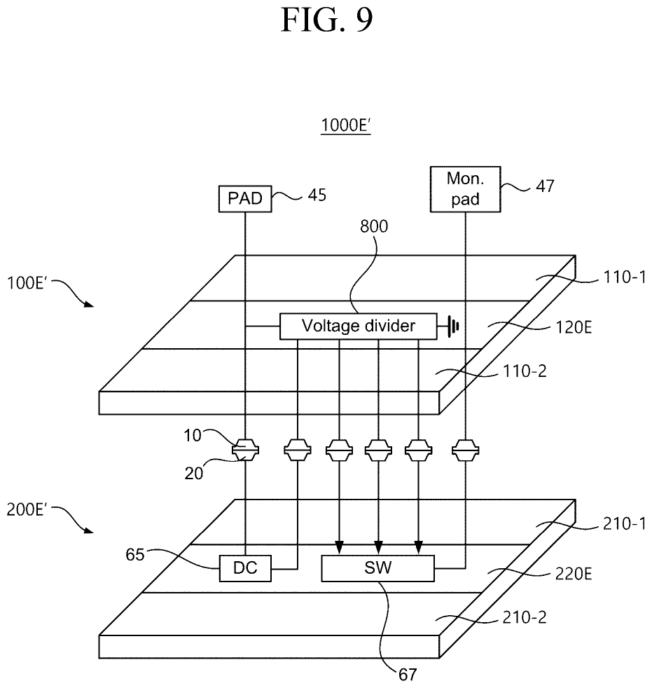

Hereinafter, an example of using a variable resistor according to example embodiments will be described with reference to FIG. 9. According to example embodiments, intermediate voltages generated by a voltage divider may be monitored. A semiconductor memory device 1000E′ of FIG. 9 has a configuration, similar to that of the semiconductor memory device 1000E described in FIGS. 8A and 8B, so duplicate descriptions will be omitted and differences will be mainly described.

Referring to FIG. 9, the semiconductor memory device 1000E′ may include a first chip 100E′ and a second chip 200E′ having a CoP structure.

The first chip 100E′ may further include a monitoring pad 47 in a pad region. The monitoring pad 47 may be a pad for monitoring the intermediate voltage generated by a voltage divider 800. The monitoring pad 47 may be connected to a switch unit 67 of the second chip 200E′ through first and second bonding metals 10 and 20.

The second chip 200E′ may include a switch unit 67 in a peripheral circuit region 220E. The switch unit 67 may select one of the intermediate voltages generated by the voltage divider 800 and apply the selected intermediate voltage to the monitoring pad 47 through first and second bonding metals 10 and 20. For example, the intermediate voltages generated by the voltage divider 800 may be applied to the switch unit 67 through the first and second bonding metals 10 and 20. A plurality of switches included in the switch unit 67 may be turned on/off under the control of a control logic to select one of the intermediate voltages.

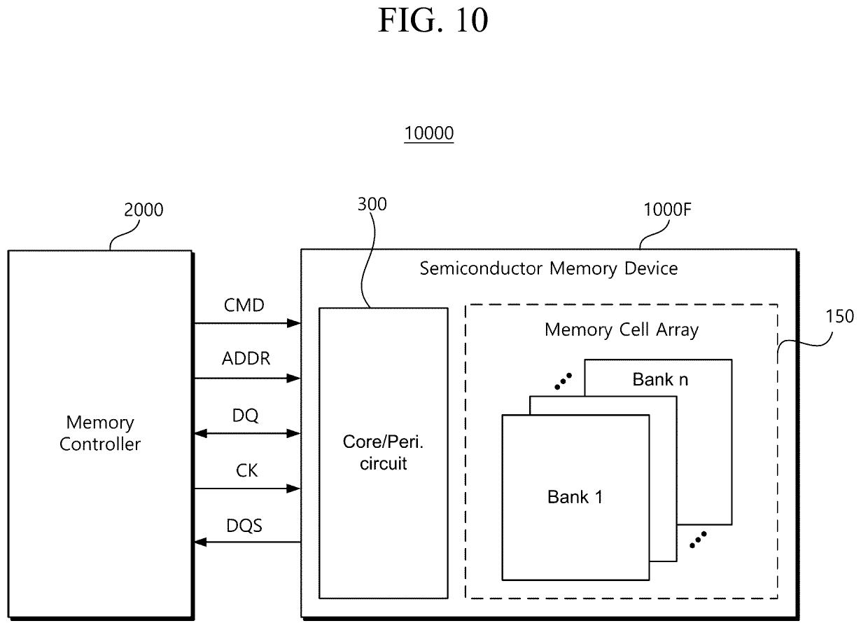

FIG. 10 is a block diagram illustrating a portion of a configuration of a semiconductor memory system according to example embodiments. Referring to FIG. 10, a semiconductor memory system 10000 may include a memory controller 2000 and a semiconductor memory device 1000F. The semiconductor memory device 1000F may be an example of the above-described semiconductor memory devices 1000, 1000A, 1000A′, 1000B, 1000C, 1000D, 1000E, and 1000E′, but example embodiments are not limited thereto. In describing FIG. 10, duplicate descriptions with what has been described above will be omitted.

The memory controller 2000 may control the semiconductor memory device 1000F. For example, the memory controller 2000 may control the semiconductor memory device 1000F based on requests of a processor supporting various applications such as server applications, personal computer (PC) applications, or mobile applications. For example, the memory controller 2000 may be included in a host including a processor, and may control the semiconductor memory device 100OF based on the requests of the processor.

The memory controller 2000 may transmit a clock signal CK, a command CMD, and/or an address ADDR to the semiconductor memory device 1000F to control the semiconductor memory device 1000F. In addition, the memory controller 2000 may transmit a data signal DQ to the semiconductor memory device 1000F or receive a data signal DQ from the semiconductor memory device 1000F. When the memory controller 2000 reads the data signal DQ from the semiconductor memory device 1000F, the memory controller 2000 may receive a data strobe signal DQS from the semiconductor memory device 1000F.

The semiconductor memory device 1000F may receive data from the memory controller 2000 and store the received data. The semiconductor memory device 1000F may read the stored data in response to a request from the memory controller 2000 and transmit the read data to the memory controller 2000.

In example embodiments, the semiconductor memory device 1000F may be a memory device including volatile memory cells. For example, the semiconductor memory device 1000F may be various DRAM devices such as double data rate synchronous dynamic random access memory (DDR SDRAM), DDR2 SDRAM, DDR3 SDRAM, DDR4 SDRAM, DDR5 SDRAM, DDR6 SDRAM, low power double data rate (LPDDR) SDRAM, LPDDR2 SDRAM, LPDDR3 SDRAM, LPDDR4 SDRAM, LPDDR4X SDRAM, LPDDR5 SDRAM, graphics double data rate synchronous graphics random access memory (GDDR SGRAM), GDDR2 SGRAM, GDDR3 SGRAM, GDDR4 SGRAM, GDDR5 SGRAM, or GDDR6 SGRAM.

In example embodiments, the semiconductor memory device 1000F may be a memory device in which DRAM dies are stacked, such as a high bandwidth memory (HBM), HBM2, and HBM3.

In example embodiments, the semiconductor memory device 1000F may be a memory module such as a dual in-line memory module (DIMM). For example, the semiconductor memory device 1000C may be a registered DIMM (RDIMM), a load reduced DIMM (LRDIMM), an unbuffered DIMM (UDIMM), a fully buffered DIMM (FB-DIMM), or a small outline DIMM (SO-DIMM). However, these are only examples, and the semiconductor memory device 1000F may be another memory module such as a single in-line memory module (SIMM).

In example embodiments, the semiconductor memory device 1000F may include an SRAM device, a NAND flash memory device, a NOR flash memory device, a resistive random access memory (RRAM) device, a ferroelectric random access memory (FRAM) device, a phase-change random access memory (PRAM) device, a thyristor random access memory (TRAM) device, a magnetic random access memory (MRAM) device, or the like.

The semiconductor memory device 1000F may include a memory cell array 150 and a core/peripheral circuit 300. In this case, the memory cell array 150 may be implemented in the above-described first chips 100, 100A, 100A′, 100B, 100C, 100D, 100E, and 100E′, and the core/peripheral circuit 300 is implemented in the above-described second chip 200, 200A, 200A′, 200B, 200C, 200D, 200E, and 200E′.

The memory cell array 150 may include a plurality of banks Bank 1 to Bank n, and each of the banks Bank 1 to Bank n may include a plurality of memory cells storing data. For case of description, an example will be provided in which each bank includes DRAM cells. However, this is only an example, and each of the banks Bank 1 to Bank n may be implemented to include volatile memory cells other than DRAM cells. In addition, each of the banks Bank 1 to Bank n may be implemented to include the same type of memory cells, or may be implemented to include different types of memory cells.

In this case, according to example embodiments, each of the banks Bank 1 to Bank n may include a plurality of cell array mats. The cell array mat may refer to a region of memory cells divided based on sub-wordline drivers.

The core/peripheral circuit 300 may include various circuits driving the memory cell array 150. For example, the core/peripheral circuit 300 may include various core circuits such as s bitline sense amplifier, a sub-wordline driver, a row decoder (or an X-decoder), or a column decoder (or a Y-decoder). The core circuits may be disposed in the above-described core regions 210-1 and 210-2. The core/peripheral circuit 300 may include various peripheral circuits such as a control logic decoding commands, an address buffer, a delayed locked loop (DLL), a data input/output (I/O) circuit, a DC circuit, or a power circuit. The peripheral circuits may be disposed in the above-described peripheral circuit region 220, 220A, 220A′, 220B, 220D, and 220E.

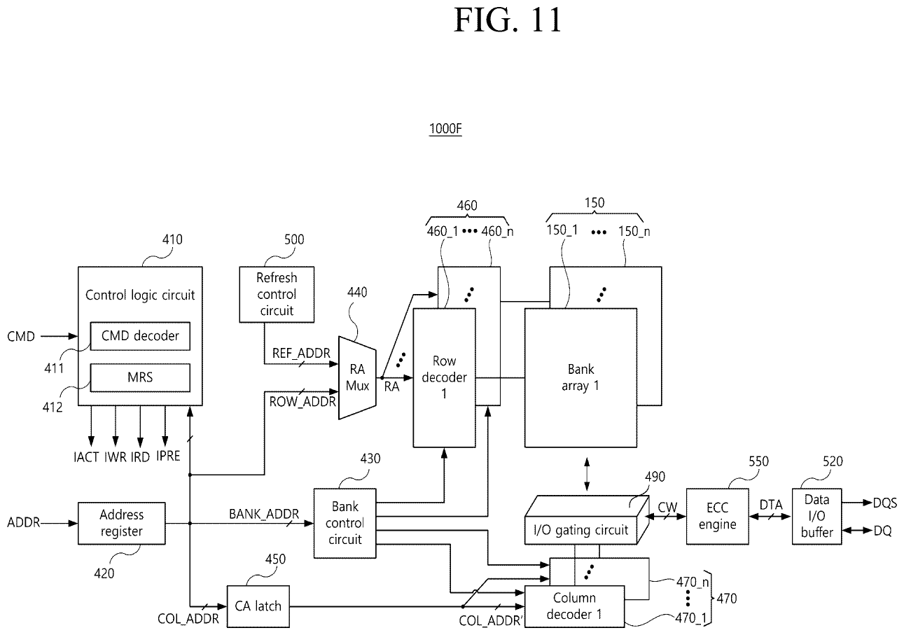

FIG. 11 is a block diagram illustrating an example of a semiconductor memory device according to example embodiments. A semiconductor memory device 1000F of FIG. 11 may be an example of the semiconductor memory device 1000F of FIG. 10, but example embodiments are not limited thereto.

Referring to FIG. 11, the semiconductor memory device 100OF may include a control logic circuit 410, an address register 420, a bank control logic 430, a refresh control circuit 500, a row address multiplexer 440, a column address latch 450, a row decoder 460, a column decoder 470, a memory cell array 150, an input/output gating circuit 490, an error correction code (ECC) engine 550, and a data input/output buffer 520. Although not illustrated in FIG. 11, the semiconductor memory device 1000F may include sub-wordline drivers and bitline sense amplifiers corresponding to each cell array mat.

In this case, according to example embodiments, the memory cell array 150 may be implemented in the above-described first chip 100, 100A, 100A′, 100B, 100C, 100D, 100E, and 100E′. In addition, the remaining circuits 410, 420, 430, 440, 450, 460, 470, 490, 500, 520, and 550, sub-wordline drivers, not illustrated, and bitline sense amplifiers, not illustrated, may be implemented in the above-described second chip 200, 200A, 200A′, 200B, 200C, 200D, 200E, and 200E′.

For example, the core circuits including the sub-wordline drivers, not illustrated, the bitline sense amplifiers, not illustrated, the row decoder 460, and the column decoder 470 may be disposed in the core region 210-1 and 210-2 of the second chip 200, 200A, 200A′, 200B, 200C, 200D, 200E, and 200E′. The peripheral circuits including the control logic circuit 410, the address register 420, the bank control logic 430, the refresh control circuit 500, the row address multiplexer 440, the column address latch 450, the input/output gating circuit 490, the ECC engine 550, and the data input/output buffer 520 may be disposed in the peripheral circuit region 220, 220A, 220A′, 220B, 220D, and 220E of the second chip 200, 200A, 200A′, 200B, 200C, 200D, 200E, and 200E′.

In example embodiments, referring to FIGS. 2B and 11, the sub-wordline drivers, not illustrated, and bitline sense amplifiers, not illustrated, may be disposed in first regions 201 of the core regions 210-1 and 210-2. Further, the row decoder 460 may be disposed in a second region 26 of the core region 210-1 and 210-2, and the column decoder 470 may be disposed in a third region 27 of the core region 210-1 and 210-2. The control logic circuit 410, the address register 420, the bank control logic 430, the refresh control circuit 500, the row address multiplexer 440, the column address latch 450, the input/output gating circuit 490, the ECC engine 550, and the data input/output buffer 520 may be disposed in the peripheral circuit region 220A, but example embodiments are not limited thereto.

The memory cell array 150 may include a plurality of bank arrays 150_1 to 150_n. Each of the plurality of bank arrays 150_1 to 150_n may include a plurality of memory cells. For example, each of the plurality of memory cells may be formed at an intersection of a corresponding wordline and a corresponding bitline. In this case, each of the plurality of bank arrays 150_1 to 150_n may include a plurality of cell array mats.

The row decoder 460 may include a plurality of sub-row decoders 460_1 to 460_n. Each of the plurality of sub-row decoders 460_1 to 460_n may be connected to a corresponding bank array, among the plurality of bank arrays 150_1 to 150_n.

The column decoder 470 may include a plurality of sub-column decoders 470_1 to 470_n. Each of the plurality of sub-column decoders 470_1 to 470_n may be connected to a corresponding bank array, among the plurality of bank arrays 150_1 to 150_n.

For example, the plurality of bank arrays 150_1 to 150_n, the plurality of sub-column decoders 470_1 to 470_n, and the plurality of sub-row decoders 460_1 to 460_n may each constitute a plurality of banks. For example, a first bank array 150_1, a first sub-column decoder 470_1, and a first sub-row decoder 460_1 may be included in a first bank.

The address register 420 may receive an address ADDR, including a bank address BANK_ADDR, a row address ROW_ADDR, and a column address COL_ADDR, from the memory controller 2000. The address register 420 may provide the received bank address BANK_ADDR to the bank control logic 430, provide the received row address ROW_ADDR to the row address multiplexer 440, and provide the received column address COL_ADDR to the column address latch 450.

The bank control logic 430 may generate bank control signals in response to the bank address BANK_ADDR. For example, a row decoder corresponding to the bank address BANK_ADDR, among the plurality of sub-row decoders 460_1 to 460_n, may be activated in response to the above-mentioned bank control signals. A column decoder corresponding to the bank address BANK_ADDR, among the plurality of sub-column decoders 470_1 to 470_n, may be activated in response to the above bank control signals.

The row address multiplexer 440 may receive a row address ROW_ADDR from the address register 420 and a refresh row address REF_ADDR from the refresh control circuit 500. The row address multiplexer 440 may selectively output the row address ROW_ADDR or the refresh row address REF_ADDR as a row address RA. The row address RA, output from the row address multiplexer 440, may be applied to each of the plurality of sub-row decoders 460_1 to 460_n.

The refresh control circuit 500 may sequentially increase or decrease the refresh row address REF_ADDR in response to refresh signals from the control logic circuit 410.

The row decoder selected by the bank control logic 430, among the plurality of sub-row decoders 460_1 to 460_n, may activate a wordline corresponding to the row address RA output from the row address multiplexer 440. For example, the selected row decoder may apply a drive signal to the wordline corresponding to the row address.

In this case, according to example embodiments, the drive signal may be applied to a main wordline corresponding to the row address. The drive signal applied to the main wordline may be applied to the sub-wordline drivers driving the wordline corresponding to the row address. Accordingly, the wordline corresponding to the row address may be activated by the sub-wordline drivers.

The column address latch 450 may receive a column address COL_ADDR from the address register 420 and temporarily store the received column address COL_ADDR. In addition, for example, the column address latch 450 may incrementally increase the received column address COL_ADDR in burst mode. The column address latch 450 may apply the temporarily stored or incrementally increased column address COL_ADDR′ to each of the plurality of sub-column decoders 470_1 to 470_n.

The column decoder activated by the bank control logic 430, among the plurality of sub-column decoders 470_1 to 470_n, may activate a sense amplifier corresponding to the bank address BANK_ADDR and the column address COL_ADDR through the input/output gating circuit 490.

The input/output gating circuit 490 may include circuits gating input/output data. In addition, the input/output gating circuit 490 may include data latches, storing codewords CWs output from a plurality of bank arrays 150_1 to 150_n, and write drivers writing data in the plurality of bank arrays 150_1 to 150_n.

In example embodiments, during a read operation, a codeword CW read from a selected bank array among the plurality of bank arrays 150_1 to 150_n may be sensed by a sense amplifier corresponding to the selected bank array and may be stored in the data latches of the input/output gating circuit 490. Additionally, the codeword CW stored in the data latches may be provided to the data output buffer 520 as data DTA after ECC decoding is performed by the ECC engine 550. The data output buffer 520 may generate a data signal DQ based on the data DTA and provide the data signal DQ to the memory controller 2000 along with a strobe signal DQS.

In example embodiments, during a write operation, data DTA to be written in the selected bank array among the plurality of bank arrays 150_1 to 150_n may be received by the data output buffer 520 as the data signal DQ. The data output buffer 520 may convert the data signal DQ into data DTA and provide the data DTA to the ECC engine 550. The ECC engine 550 may generate parity bits (or parity data) based on the data DTA, and may provide a codeword CW including the data DTA and the parity bits to the input/output gating circuit 490. The input/output gating circuit 490 may write the codeword CW to the selected bank array.

In a write operation, the data output buffer 520 may convert the data signal DQ into data DTA and provide the data DTA to the ECC engine 550. In a read operation, the data output buffer 520 may convert the data DTA, provided from the ECC engine 550, into the data signal DQ.

The ECC engine 550 may perform ECC encoding on data DTA during a write operation. The ECC engine 550 may perform ECC decoding on codewords CW during a read operation.

The control logic circuit 410 may control an operation of the semiconductor memory device 1000F. For example, the control logic circuit 410 may generate control signals such that the semiconductor memory device 1000F performs write, read, and refresh operations. The control logic circuit 410 may include a command decoder 411, decoding the commands CMD received from the memory controller 2000, and a mode register set (MRS) 412 setting an operating mode of the semiconductor memory device 1000F.

The command decoder 411 may decode the command CMD to generate internal command signals such as an internal active signal IACT, an internal precharge signal IPRE, an internal read signal IRD, or an internal write signal IWR. In addition, the command decoder 411 may decode a chip select signal and a command/address signal to generate control signals corresponding to the command CMD.

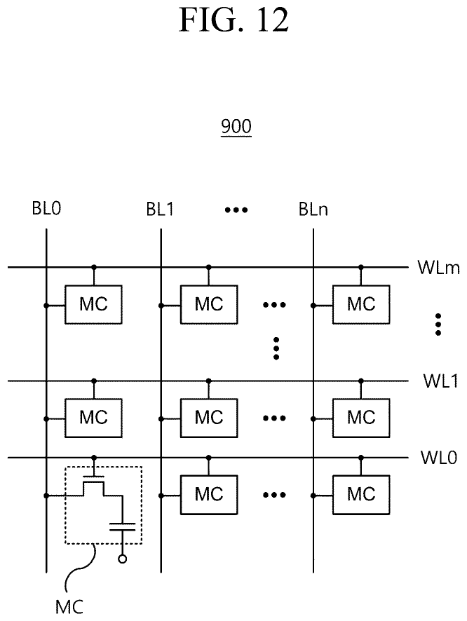

FIG. 12 is a diagram illustrating a portion of a configuration of a memory cell array according to example embodiments. Referring to FIG. 12, a memory cell array 900 may include a plurality of wordlines WL0 to WLm, a plurality of bitlines BL0 to BLn, and a plurality of memory cells MCs disposed at intersections of the wordlines WL0 to WLm and the bitlines BL0 to BLn.

According to example embodiments, each memory cell MC may be a DRAM cell. For example, each of the memory cells MCs may include a cell transistor, connected to a wordline and a bitline, and a cell capacitor connected to the cell transistor. In this case, according to example embodiments, the cell transistor may be a vertical channel transistor.

Since the vertical channel transistor has a structure different from that of the horizontal channel transistor, the vertical channel transistor and the horizontal channel transistor may be implemented using different wafers. For example, the vertical channel transistors may be implemented on a first chip 100, 100A, 100A′, 100B, 100C, 100D, 100E, and 100E′ and the horizontal channel transistors may be implemented on a second chip 200, 200A, 200A′, 200B, 200C, 200D, 200E, and 200E′.

Therefore, according to example embodiments, the memory cells included in the memory cell array 900 may be implemented in a first chip 100, 100A, 100A′, 100B, 100C, 100D, 100E, or 100E′ including vertical channel transistors, and the core circuits and peripheral circuits may be implemented in a second chip 200, 200A, 200A′, 200B, 200C, 200D, 200E, or 200E′ including horizontal channel transistors. Accordingly, a semiconductor memory device 1000, 1000A, 1000A′, 1000B, 1000C, 1000D, 1000E, or 1000E′ having a CoP structure may be implemented by bonding the first chip 100, 100A, 100A′, 100B, 100C, 100D, 100E, or 100E′ and the second chip 200, 200A, 200A′, 200B, 200C, 200D, 200E, or 200E′.

Dummy cell transistors may be implemented in a first chip 100, 100A, 100A′, 100B, 100C, 100D, 100E, or 100E′ including vertical channel transistors. For example, the dummy cell transistors may be implemented in a dummy region 120, 120A, 120A′, 120B, 120C, 120D, or 120E of the first chip 100, 100A, 100A′, 100B, 100C, 100D, 100E, or 100E′. In this case, the dummy cell transistor may not be connected to a cell capacitor, unlike the cell transistor included in the cell region 110-1 and 110-2, because the dummy cell transistor is not used to store data. For example, the dummy region 120, 120A, 120A′, 120B, 120C, 120D, and 120E may not include cell capacitors.

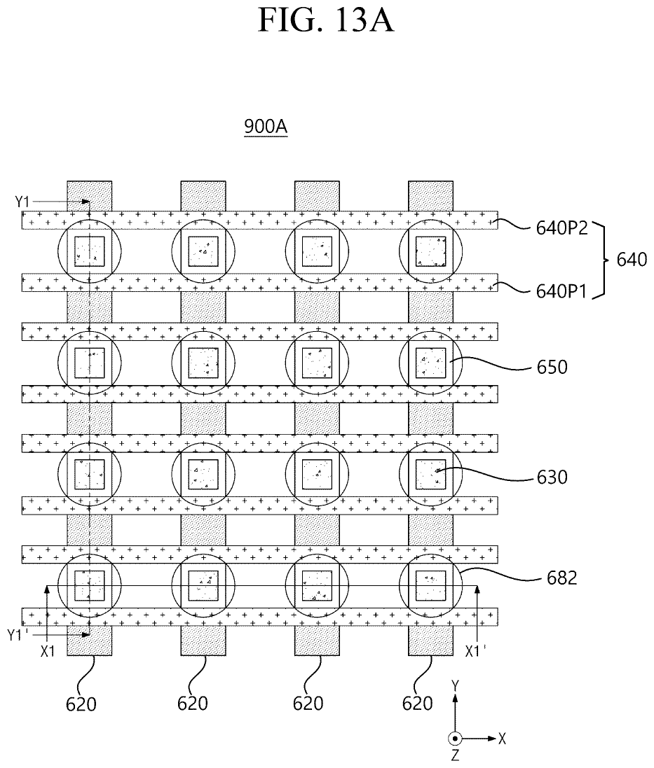

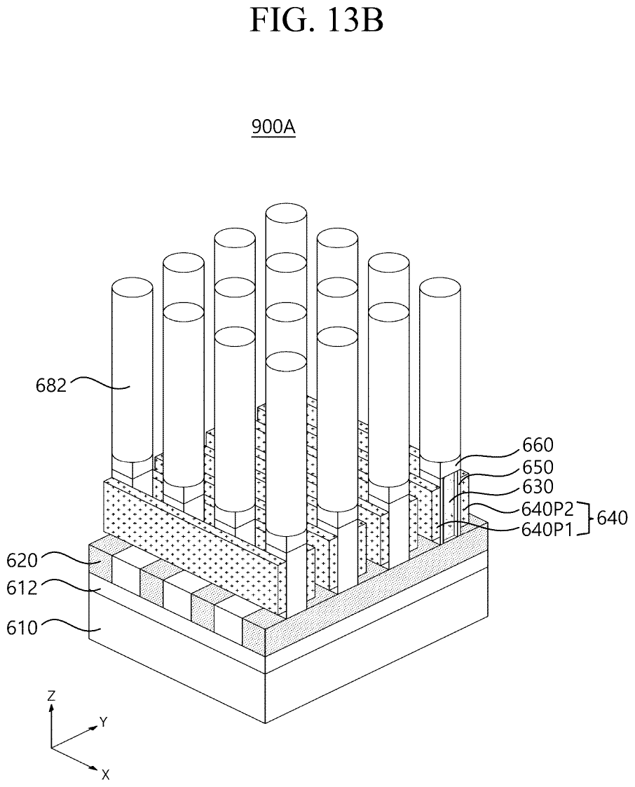

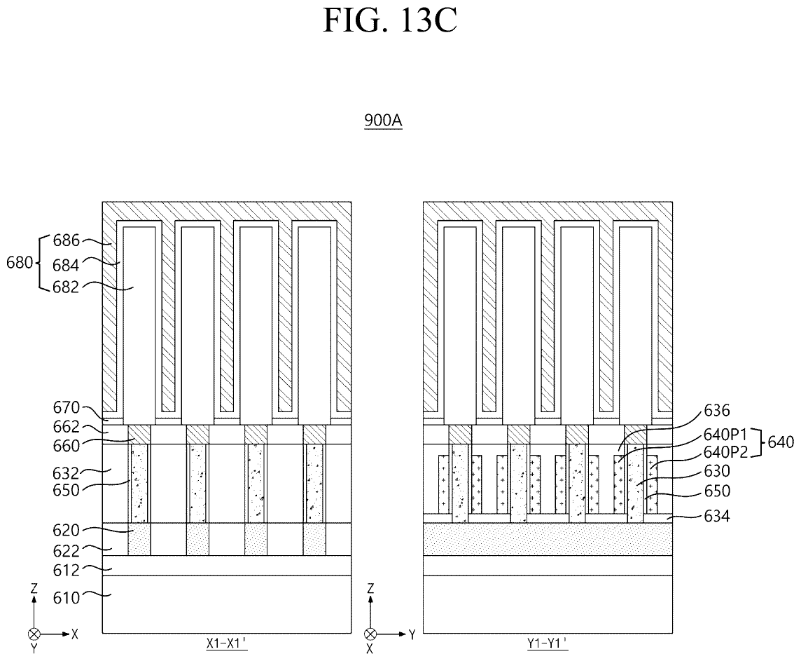

Hereinafter, example embodiments of a memory cell array including a vertical channel transistor will be described in more detail with reference to FIGS. 13A, 13B, and 13C. FIG. 13A is a diagram illustrating a layout of a memory cell array according to example embodiments, FIG. 13B is a perspective view illustrating the memory cell array of FIG. 13A, and FIG. 13C is a cross-sectional view taken along lines X-X1′ and Y-Y1′ of FIG. 13A.

Referring to FIGS. 13A, 13B, and 13C, the memory cell array 900A may include a substrate 610, a plurality of first conductive lines 620, a channel layer 630, a gate electrode 640, a gate insulating layer 650, and a capacitor structure 680. In this case, the memory cell array 900A may include a vertical channel transistor VCT. The vertical channel transistor may refer to a structure in which a channel length of the channel layer 630 extends in a vertical direction from the substrate 610.

An insulating layer 612 may be disposed on the substrate 610, and a plurality of first conductive lines 620 may be spaced apart from each other in a first direction (an X-direction) and extend in second direction (a Y-direction) on the insulating layer 612. A plurality of first insulating patterns 622 may be disposed to partially or fully fill spaces between the plurality of first conductive lines 620 on the insulating layer 612. The plurality of first insulating patterns 622 may extend in second direction Y, and upper surfaces of the plurality of first insulating patterns 622 may be disposed at the same level as upper surfaces of the plurality of first conductive lines 620. The plurality of first conductive lines 620 may serve as bitlines of the memory cell array 900A.

In example embodiments, the plurality of first conductive lines 620 may include doped polysilicon, metal, conductive metal nitride, conductive metal silicide, conductive metal oxide, or combinations thereof. For example, the plurality of first conductive lines 620 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOX, or combinations thereof, but example embodiments are not limited thereto. The plurality of first conductive lines 620 may have a single-layer structure or a multilayer structure including the above-described materials. In example embodiments, the plurality of first conductive lines 620 may include a two-dimensional semiconductor material. For example, the two-dimensional semiconductor material may include graphene, carbon nanotube, or a combination thereof.

The channel layers 630 may be disposed to be spaced apart from each other in the first direction (X-direction) and the second direction (Y-direction), for example, in a matrix, on the plurality of first conductive lines 620. The channel layer 630 may have a first width in the first direction (X-direction) and a first height in a third direction (Z-direction). In this case, the first height may be greater than the first width. For example, the first height may be about 2 to 10 times the first width, but example embodiments are not limited thereto. A bottom portion of the channel layer 630 may serve as a first source/drain region, not illustrated, and an upper portion of the channel layer 630 may serve as a second source/drain region. A portion of the channel layer 630 between the first and second source/drain regions may serve as a channel region, not illustrated.

In example embodiments, the channel layer 630 may include an oxide semiconductor. For example, the oxide semiconductor may include InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, InxGayO, or combinations thereof. The channel layer 630 may have a single-layer structure or a multilayer structure including the oxide semiconductor. In some embodiments, the channel layer 630 may have a bandgap energy that is greater than the bandgap energy of silicon. For example, the channel layer 630 may have bandgap energy of about 1.5 eV to 5.6 eV. For example, the channel layer 630 may have optimal or excellent channel performance when having bandgap energy of about 2.0 eV to 4.0 eV. For example, the channel layer 630 may be polycrystalline or amorphous, but example embodiments are not limited thereto. In example embodiments, the channel layer 630 may include a two-dimensional semiconductor material. For example, the two-dimensional semiconductor material may include graphene, carbon nanotube, or a combination thereof.

The gate electrode 640 may extend in the first direction (X-direction) on opposite sidewalls of the channel layer 630. The gate electrode 640 may include a first sub-gate electrode 640P1, opposing a first sidewall of the channel layer 630, and a second sub-gate electrode 640P2 opposing a second sidewall opposite the first sidewall of the channel layer 630. Since a single channel layer 630 is disposed between the first sub-gate electrode 640P1 and the second sub-gate electrode 640P2, the memory cell array 900A may have a dual-gate transistor structure. However, example embodiments are not limited thereto, and the second sub-gate electrode 640P2 may be omitted and only the first sub-gate electrode 640P1 opposing the first sidewall of the channel layer 630 may be formed to implement a single-gate transistor structure.

The gate electrode 640 may include doped polysilicon, metal, conductive metal nitride, conductive metal silicide, conductive metal oxide, or combinations thereof. For example, the gate electrode 640 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOX, or combinations thereof, but example embodiments are not limited thereto.

The gate insulating layer 650 may surround a sidewall of the channel layer 630 and may be interposed between the channel layer 630 and the gate electrode 640. For example, as illustrated in FIG. 13A, the entire sidewall of the channel layer 630 may be surrounded by the gate insulating layer 650, and a portion of the sidewall of the gate electrode 640 may be in contact with the gate insulating layer 650. In some embodiments, the gate insulating layer 650 may extend in a direction in which the gate electrode 640 extends, for example, the first direction (X-direction), and only two sidewalls of the channel layer 630, opposing the gate electrode 640, may be in contact with the gate insulating layer 650.

In example embodiments, the gate insulating layer 650 may be formed of a silicon oxide, a silicon nitride, a high-κ dielectric having a higher dielectric constant than a silicon oxide, or combinations thereof. The high-κ dielectric layer may include a metal oxide or a metal oxynitride. For example, the high-κ dielectric layer may be used as the gate insulating layer 650 and include HfO2, HfSiO, HfSiON, HfTaO, HfTiO, HfZrO, ZrO₂, Al₂O₃, or combinations thereof, but example embodiments are not limited thereto.

A plurality of second insulating patterns 632 may extend in the second direction (Y-direction) on the plurality of first insulating patterns 622, and a channel layer 630 may be disposed between two adjacent second insulating patterns 632. In addition, a first filling layer 634 and a second filling layer 636 may be disposed in a space between two adjacent channel layers 630, between two adjacent second insulating patterns 632. The first filling layer 634 may be disposed in a bottom portion of the space between the two adjacent channel layers 630, and the second filling layer 636 may be formed on the first filling layer 634 to partially or fully fill the rest of the space between the two adjacent channel layers 630. An upper surface of the second filling layer 636 may be disposed at the same level as an upper surface of the channel layer 630, and the second filling layer 636 may cover or overlap the upper surface of the gate electrode 640. In contrast, the plurality of second insulating patterns 632 may include a material layer continuous or adjacent to the plurality of first insulating patterns 622, or the second filling layer 636 may include a material layer continuous or adjacent to the first filling layer 634.

Capacitor contacts 660 may be disposed on the channel layers 630. The capacitor contacts 660 may be disposed to vertically overlap the channel layers 630 and disposed to be spaced apart from each other in the first direction (X-direction) and the second direction (Y-direction), for example, in a matrix. The capacitor contact 660 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOX, or combinations thereof, but example embodiments are not limited thereto. An upper insulating layer 662 may surround a sidewall of the capacitor contact 660 on the plurality of second insulating patterns 632 and the second filling layer 636.

An etch-stop layer 670 may be disposed on the upper insulating layer 662, and a capacitor structure 680 may be disposed on the etch-stop layer 670. A capacitor structure 680 may include a lower electrode 682, a capacitor dielectric layer 684, and an upper electrode 686.

The lower electrode 682 may be electrically connected to an upper surface of the capacitor contact 660 through the etch-stop layer 670. The lower electrode 682 may be formed in a pillar type extending in the third direction (Z-direction), but example embodiments are not limited thereto. In example embodiments, the lower electrode 682 may be disposed to vertically overlap the capacitor contact 660 and disposed to be spaced apart from each other in the first direction (X-direction) and the second direction (Y-direction), for example, in a matrix. In contrast, a landing pad, not illustrated, may be further disposed between the capacitor contact 660 and the lower electrode 682, and thus the lower electrode 682 may be disposed in a hexagonal shape.

Although not illustrated in FIGS. 13B and 13C, according to example embodiments, a plurality of metal layers may be formed in a lower portion of the memory cell array 900A. In addition, a pad region may be formed on the memory cell array 900A.

According to example embodiments, the above-described dummy cell transistors may be formed together in the dummy region 120, 120A, 120A′, 120B, 120C, 120D, or 120E when the memory cell array 900A is formed in the cell regions 110-1 and 110-2, but example embodiments are not limited thereto. In this case, the capacitor contact 660 or the capacitor structure 680 may not be formed in the dummy region 120, 120A, 120A′, 120B, 120C, 120D, or 120E. In addition, a length of the gate electrode 640 of the memory cell array 900A and a length of the gate electrodes of the dummy cell transistors may be different from each other.

According to example embodiments, the above-described dummy cell transistors may be NMOS transistors, but example embodiments are not limited thereto.

Although the above description has been made with reference to the case in which the dummy cell transistors are vertical channel transistors, example embodiments are not limited thereto. According to example embodiments, dummy cell transistors may be formed using horizontal channel transistors.

In addition, the above description has been made with reference to the case on which the vertical channel transistor includes two gate electrodes, but example embodiments are not limited thereto. According to example embodiments, vertical channel transistors including a single gate electrode may be used as dummy cell transistors.

In addition, although the above description has been made with reference to examples in which two chips, for example, a first chip 100, 100A, 100A′, 100B, 100C, 100D, 100E, or 100E′ and a second chip 200, 200A, 200A′, 200B, 200C, 200D, 200E, or 200E′ be included in a CoP structure, but example embodiments are not limited thereto. For example, three or more chips may be stacked to implement a semiconductor memory device having a CoP structure. For example, at least one chip with implemented memory cell arrays and at least one chip with implemented core/peripheral circuits may be stacked to implement a semiconductor memory device having a CoP structure.

According to the above-described various embodiments, a variable resistor may be implemented in the dummy region of a semiconductor memory device having a CoP structure. As a result, a chip-size gain may be obtained.

As set forth above, according to example embodiments, a variable resistor may be implemented in a dummy region of a semiconductor memory device. As a result, a chip-size gain may be obtained.

While example embodiments have been shown and described above, it will be apparent to those skilled in the art that modifications and variations could be made without departing from the scope of the present inventive concept as defined by the appended claims.

What is claimed is:

1. A semiconductor memory device comprising:
a first chip comprising a cell region that includes memory cells and a dummy region that includes a set of dummy cell transistors; and
a second chip comprising core circuits and peripheral circuits configured to control operation of the memory cells, the second chip overlapping at least a part of the first chip along a vertical direction,
wherein the dummy region of the first chip comprises at least one variable resistor that includes the set of dummy cell transistors.

2. The semiconductor memory device of claim 1, wherein the set of dummy cell transistors comprise vertical channel transistors.

3. The semiconductor memory device of claim 2, wherein the vertical channel transistors comprises first gate electrodes on a first side of a channel layer, and second gate electrodes on a second side of the channel layer.

4. The semiconductor memory device of claim 3, wherein the at least one variable resistor comprises a set of variable resistors, each variable resistor of the set of variable resistors including a subset of dummy cell transistors, among the set of dummy cell transistors, electrically connected in series with one another, and
wherein the first gate electrodes and the second gate electrodes of the subset of dummy cell transistors included in the set of variable resistors correspond to a first gate line and a second gate line, respectively.

5. The semiconductor memory device of claim 4, wherein the set of variable resistors include a first variable resistor and a second variable resistor,
wherein a first resistance value of the first variable resistor is configured based on a first voltage and a second voltage respectively applied to the first gate line and the second gate line of the first variable resistor, and
wherein a second resistance value of the second variable resistor is configured based on a third voltage and a fourth voltage respectively applied to the first gate line and the second gate line of the second variable resistor.

6. The semiconductor memory device of claim 5, wherein the first voltage may be controlled independently from the third voltage.

7. The semiconductor memory device of claim 1, wherein the at least one variable resistor comprises a plurality of variable resistors,
wherein the dummy region of the first chip comprises a voltage divider comprising the plurality of variable resistors electrically connected in series, and
wherein the voltage divider is configured to generate at least one intermediate voltage based on a ratio of respective resistance values of the plurality of variable resistors included in the voltage divider.

8. The semiconductor memory device of claim 7, wherein at least one of the peripheral circuits of the second chip operates based on the at least one intermediate voltage as a reference voltage.

9. The semiconductor memory device of claim 1, wherein the at least one variable resistor comprises a third variable resistor and a fourth variable resistor, the semiconductor memory device further comprising:
a low-dropout (LDO) regulator comprising the third variable resistor and the fourth variable resistor connected in series, an amplifier, and a pass transistor,
wherein the dummy region of the first chip comprises the third variable resistor and the fourth variable resistor of the LDO regulator, and
wherein the second chip comprises the amplifier and the pass transistor of the LDO regulator.

10. The semiconductor memory device of claim 9, wherein the amplifier comprises a first input terminal configured to receive a reference voltage, a second input terminal electrically connected to a first end of the third variable resistor and a first end of the fourth variable resistor, and an output terminal electrically connected to a gate terminal of the pass transistor,
wherein the gate terminal of the pass transistor is electrically connected to the output terminal of the amplifier, a source terminal of the pass transistor is electrically connected to a power supply, and a drain terminal of the pass transistor is electrically connected to a second end of the third variable resistor, and
wherein a second end of the fourth variable resistor is electrically connected to ground.

11. The semiconductor memory device of claim 10, wherein an output voltage of the LDO regulator is configured to be output from a drain terminal of the pass transistor and depends on a ratio of respective resistance values of the third variable resistor and the fourth variable resistor.

12. The semiconductor memory device of claim 11, wherein at least one of the peripheral circuits of the second chip operates based on the output voltage of the LDO regulator.

13. The semiconductor memory device of claim 1, wherein the first chip and the second chip are electrically connected to each other by first bonding metals in a lower portion of the first chip and second bonding metals in an upper portion of the second chip.

14. The semiconductor memory device of claim 1, wherein the core circuits comprise a sub-wordline driver and a bitline sense amplifier, and
wherein first ones of the peripheral circuits are configured to decode commands and second ones of the peripheral circuits are configured to control an input and/or output of address and data.

15. The semiconductor memory device of claim 14, wherein the second chip comprises a core region corresponding to the cell region and a peripheral circuit region corresponding to the dummy region, and
wherein the core region and the peripheral circuit region comprise the core circuits and the peripheral circuits, respectively.

16. A semiconductor memory device comprising:
a first chip comprising a cell region that includes memory cells and a dummy region that includes a set of dummy cell transistors; and
a second chip comprising core circuits and peripheral circuits configured to control operation of the memory cells, the second chip overlapping at least a part of the first chip along a vertical direction,
wherein the dummy region of the first chip comprises:
a first variable resistor including a first subset of dummy cell transistors, among the set of dummy cell transistors, electrically connected in series with one another; and
a second variable resistor including a second subset of dummy cell transistors, among the set of dummy cell transistors, electrically connected in series with one another,
wherein the second chip comprises an amplifier and a pass transistor, and
wherein the first and second variable resistors, the amplifier, and the pass transistor are included in a low-dropout (LDO) regulator.

17. The semiconductor memory device of claim 16, wherein the first set of dummy cell transistors includes vertical channel transistors that share a first gate line, and
wherein the second set of dummy cell transistors includes vertical channel transistors that share a second gate line.

18. The semiconductor memory device of claim 17, wherein a first resistance value of the first variable resistor and a second resistance value of the second variable resistor are controlled independently based on a first voltage applied to the first gate line and a second voltage applied to the second gate line, respectively, and
wherein an output voltage of the LDO regulator depends on a ratio of the first resistance value and the second resistance value.

19. The semiconductor memory device of claim 16, further comprises:
first bonding metals in a lower portion of the first chip; and
second bonding metals in an upper portion of the second chip, and
wherein the first bonding metals and the second bonding metals are configured to electrically connect the first chip and the second chip, and
wherein the first and the second variable resistors are electrically connected to the amplifier and the pass transistor through the first and the second bonding metals.

20. A semiconductor memory device comprising:
a first chip comprising a cell region including memory cells and a dummy region including dummy cell transistors; and
a second chip comprising core circuits and peripheral circuits configured to control operation of the memory cells, the first chip and the second chip overlap along a vertical direction,
wherein dummy cell transistors are vertical channel transistors,
wherein the dummy region of the first chip comprises a plurality of variable resistors that each include ones of the dummy cell transistors electrically connected in series to one another, and
wherein a respective resistance value of each of the plurality of variable resistors is controlled independently based on a voltage applied to a gate line of the ones of the dummy cell transistors included in a corresponding one of the plurality of variable resistors.
